(19) United States
(12) Patent Application Publication
(10) Pub. No.: US 2024/0404946 A1
(43) Pub. Date: Dec. 5, 2024

(54) SEMICONDUCTOR STORAGE DEVICE

(71) Applicant: Kioxia Corporation, Tokyo (JP)

(72) Inventors: Yoshiyuki HORII, Kasugai Aichi (JP); Hideo WADA, Yokkaichi Mie (JP)

(73) Assignee: Kioxia Corporation, Tokyo (JP)

(21) Appl. No.: 18/664,536

(22) Filed: May 15, 2024

(30) Foreign Application Priority Data
May 31, 2023 (JP) 2023-089773

(51) Int. Cl. H01L 23/528; G11C 16/04; H01L 25/065; H10B 41/10; H10B 41/27; H10B 43/10; H10B 43/27; H10B 80/00

(52) U.S. Cl. CPC H01L 23/5283; G11C 16/0483; H01L 25/0657; H10B 41/10; H10B 41/27; H10B 43/10; H10B 43/27; H10B 80/00; H01L 2225/06506

(57) ABSTRACT

A semiconductor storage device includes a substrate, a first wiring layer, a second wiring layer, a memory cell array layer, and a first insulating layer. The memory cell array layer includes a plurality of first conductive layers that are arranged in a first direction, a first semiconductor layer that faces the plurality of first conductive layers, a first charge storage layer that is provided between the plurality of first conductive layers and the first semiconductor layer, and first and second contacts that extend in the first direction. The second wiring layer includes a second conductive layer that is connected to one end of the first semiconductor layer. The first wiring layer includes first and second electrodes that are connected to the first and second contacts. At least a part of surfaces of the first and second electrodes on a substrate side is closer to the substrate than a surface of the second conductive layer on the side opposite to the substrate in the first direction. A surface of the first electrode on the side opposite to the substrate includes a region that is not covered with the first insulating layer. A surface of the second electrode on the side opposite to the substrate is entirely covered with the first insulating layer.

### CROSS-REFERENCE TO RELATED APPLICATION(S)

This application is based upon and claims the benefit of priority from Japanese Patent Application No. 2023-089773, filed May 31, 2023, the entire contents of which are incorporated herein by reference.

### FIELD

Embodiments described herein relate generally to a semiconductor storage device.

### BACKGROUND

A semiconductor storage device including a substrate, a plurality of conductive layers that are arranged in a first direction intersecting a surface of the substrate, a semiconductor layer extending in the first direction and facing the plurality of conductive layers, and a charge storage layer provided between the plurality of conductive layers and the semiconductor layer is known.

### DESCRIPTION OF THE DRAWINGS

FIG. 1 is a schematic block diagram showing a configuration of a semiconductor storage device according to a first embodiment.

FIG. 2 is a schematic side view showing a configuration of the semiconductor storage device.

FIG. 3 is a schematic plan view showing a configuration of the semiconductor storage device.

FIG. 4 is a schematic block diagram showing a configuration of the semiconductor storage device.

FIG. 5 is a schematic circuit diagram showing a partial configuration of the semiconductor storage device.

FIG. 6 is a schematic perspective view showing a partial configuration of the semiconductor storage device.

FIG. 7 is a schematic bottom view showing a partial configuration of the semiconductor storage device.

FIG. 8 is a schematic plan view showing a partial configuration of the semiconductor storage device.

FIG. 9 is a schematic sectional view corresponding to line A1-A1′ in FIG. 7 and line B1-B1′ in FIG. 8.

FIG. 10 is a schematic sectional view corresponding to line A2-A2′ in FIG. 7 and line B2-B2′ in FIG. 8.

FIG. 11 is a schematic sectional view showing a partial configuration of the semiconductor storage device.

FIG. 12 is a schematic sectional view showing a partial configuration of the semiconductor storage device.

FIG. 13 is a schematic plan view showing a partial configuration of the semiconductor storage device.

FIG. 14 is a schematic plan view showing a partial configuration of the semiconductor storage device.

FIG. 15 is a schematic plan view showing a partial configuration of the semiconductor storage device.

FIG. 16 is a schematic sectional view showing a partial configuration of the semiconductor storage device.

FIG. 17 is a schematic plan view and a sectional view showing a partial configuration of the semiconductor storage device.

FIG. 18 is a schematic plan view and a sectional view showing a partial configuration of the semiconductor storage device.

FIG. 19 is a schematic sectional view showing a manufacturing method of the semiconductor storage device.

FIG. 20 is a schematic sectional view showing the manufacturing method.

FIG. 21 is a schematic sectional view showing the manufacturing method.

FIG. 22 is a schematic sectional view showing the manufacturing method.

FIG. 23 is a schematic sectional view showing the manufacturing method.

FIG. 24 is a schematic sectional view showing the manufacturing method.

FIG. 25 is a schematic sectional view showing the manufacturing method.

FIG. 26 is a schematic sectional view showing the manufacturing method.

FIG. 27 is a schematic sectional view showing the manufacturing method.

FIG. 28 is a schematic sectional view showing the manufacturing method.

FIG. 29 is a schematic sectional view showing a partial configuration of the semiconductor storage device.

FIG. 30 is a schematic sectional view showing a partial configuration of a semiconductor storage device according to a second embodiment.

FIG. 31 is a schematic plan view showing a partial configuration of the semiconductor storage device.

FIG. 32 is a schematic plan view showing a partial configuration of the semiconductor storage device.

FIG. 33 is a schematic sectional view showing a partial configuration of the semiconductor storage device.

FIG. 34 is a schematic plan view and a sectional view showing a partial configuration of the semiconductor storage device.

FIG. 35 is a schematic plan view and a sectional view showing a partial configuration of the semiconductor storage device.

FIG. 36 is a schematic sectional view showing a manufacturing method of the semiconductor storage device.

FIG. 37 is a schematic sectional view showing the manufacturing method.

FIG. 38 is a schematic sectional view showing the manufacturing method.

FIG. 39 is a schematic sectional view showing a partial configuration of the semiconductor storage device.

FIG. 40 is a schematic plan view showing a partial configuration of a semiconductor storage device according to other embodiments.

### DETAILED DESCRIPTION

Embodiments provide a semiconductor storage device that can be suitably manufactured.

In general, according to at least one embodiment, a semiconductor storage device includes a substrate, a first wiring layer, a second wiring layer provided between the substrate and the first wiring layer, a memory cell array layer provided between the substrate and the second wiring layer, and a first insulating layer provided on a side opposite to the substrate with respect to the first wiring layer. The memory cell array layer includes a plurality of first conductive layers that are arranged in a first direction intersecting a surface of the substrate, a first semiconductor layer that extends in the first direction and that faces the plurality of first conductive layers, a first charge storage layer that is provided between the plurality of first conductive layers and the first semiconductor layer, a first contact that extends in the first direction, and a second contact that extends in the first direction. The second wiring layer includes a second conductive layer that is electrically connected to one end of the first semiconductor layer. The first wiring layer includes a first electrode that is electrically connected to the first contact, and a second electrode that is electrically connected to the second contact. At least a part of a surface of the first electrode on a substrate side and at least a part of a surface of the second electrode on the substrate side are closer to the substrate than a surface of the second conductive layer on the side opposite to the substrate in the first direction. A surface of the first electrode on the side opposite to the substrate includes a region that is not covered with the first insulating layer. A surface of the second electrode on the side opposite to the substrate is entirely covered with the first insulating layer.

Next, the semiconductor storage device according to the embodiment will be described in detail with reference to the drawings. The following embodiment is only an example, and is not intended to limit the present disclosure.

The term “semiconductor storage device” used in the present specification may mean a memory die (memory chips) or may mean a memory system including a controller die such as a memory card and an SSD. Further, the term “semiconductor storage device” may mean a configuration including a host computer such as a smartphone, a tablet terminal, and a personal computer.

In the present specification, when a first configuration is said to be “electrically connected” to a second configuration, the first configuration may be directly connected to the second configuration, or the first configuration may be connected to the second configuration via wiring, a semiconductor member, a transistor, or the like. For example, when three transistors are connected in series, the first transistor is “electrically connected” to the third transistor even though the second transistor is in an OFF state.

In the present specification, when the first configuration is said to be “connected between” the second configuration and the third configuration may mean that the first configuration, the second configuration, and the third configuration are connected in series and the second configuration is connected to the third configuration via the first configuration.

In addition, in the present specification, when a circuit or the like is said to “cause two pieces of wirings and the like to be electrically connected” may mean, for example, that the circuit or the like includes a transistor and the like, the transistor and the like are provided on a current path between the two pieces of wirings and the like, and the transistor and the like are in an ON state.

In addition, in the present specification, a predetermined direction parallel to an upper surface of a substrate is referred to as an X direction, a direction which is parallel to the upper surface of the substrate and is perpendicular to the X direction is referred to as a Y direction, and a direction perpendicular to the upper surface of the substrate is referred to as a Z direction.

In addition, in the present specification, a direction along a predetermined surface may be referred to as a first direction, a direction intersecting the first direction along the predetermined surface may be referred to as a second direction, and a direction intersecting the predetermined surface may be referred to as a third direction. The first direction, the second direction, and the third direction may or may not correspond to any one of the X direction, the Y direction, and the Z direction.

In addition, in the present specification, expressions such as “up” and “down” are based on the substrate. For example, a direction away from the substrate along the Z direction is referred to as up, and a direction toward the substrate along the Z direction is referred to as down. Further, when referring to a lower surface or a lower end of a certain configuration, it means a surface or an end portion of this configuration on the substrate side. When referring to an upper surface or an upper end, it means a surface or an end portion of this configuration on a side opposite to the substrate. In addition, a surface intersecting the X direction or the Y direction is referred to as a side surface or the like.

Further, in the present specification, when referring to a “width”, a “length”, a “thickness”, or the like in a predetermined direction for a configuration, a member, and the like, this may mean the width, the length, the thickness, or the like in a cross section or the like observed by scanning electron microscopy (SEM), transmission electron microscopy (TEM), or the like.

### First Embodiment

### Memory System 10

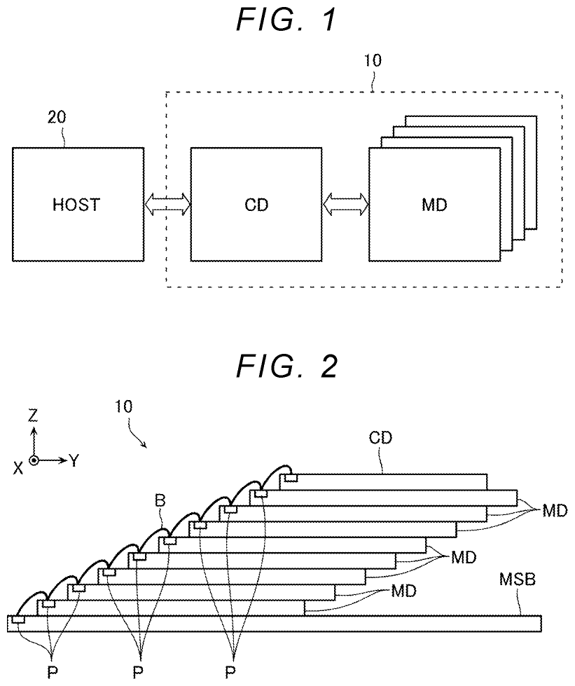

FIG. 1 is a schematic block diagram showing a configuration of a semiconductor storage device according to a first embodiment.

The memory system 10 reads, writes, and erases user data according to signals transmitted from a host computer 20. The memory system 10 is, for example, a memory card, SSD, or other system capable of storing user data. The memory system 10 includes a plurality of memory dies MD that store user data, and a controller die CD connected to the plurality of memory dies MD and the host computer 20. The controller die CD includes, for example, a processor and a RAM, and performs processing such as conversion between a logical address and a physical address, bit error detection/correction, garbage collection (that is, compaction), and wear leveling.

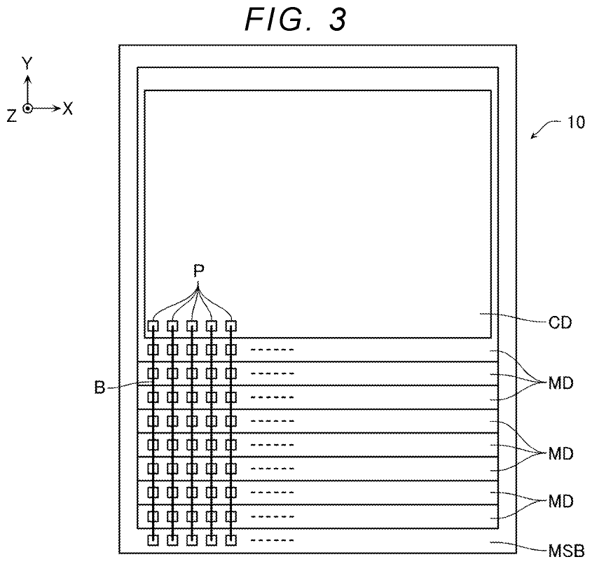

FIG. 2 is a schematic side view showing a configuration of the memory system 10 according to the present embodiment. FIG. 3 is a schematic plan view showing the same configuration. For convenience of description, a part of the configuration is omitted in FIGS. 2 and 3.

As shown in FIG. 2, the memory system 10 according to the present embodiment includes a mounting substrate MSB, a plurality of memory dies MD stacked on the mounting substrate MSB, and a controller die CD stacked on the memory die MD. A pad electrode P is provided in a region of an end portion of the upper surface of the mounting substrate MSB in the Y direction, and a part of another region of the upper surface of the mounting substrate MSB is adhered to the lower surface of the memory die MD via an adhesive or the like. The pad electrode P is provided in the region of the end portion of the upper surface of the memory die MD in the Y direction, and another region of the upper surface of the memory die MD is adhered to the lower surface of another memory die MD or the lower surface of the controller die CD via an adhesive or the like. The pad electrode P is provided in a region of an end portion of the upper surface of the controller die CD in the Y direction.

As shown in FIG. 3, each of the mounting substrate MSB, the plurality of memory dies MD, and the controller die CD includes a plurality of pad electrodes P arranged in the X direction. The plurality of pad electrodes P, which are provided on the mounting substrate MSB, the plurality of memory dies MD, and the controller die CD, are connected to each other via bonding wires B.

The configurations shown in FIGS. 2 and 3 are merely an example, and the specific configurations may be adjusted as appropriate. For example, in the example shown in FIGS. 2 and 3, the controller die CD is stacked on the plurality of memory dies MD, and such configurations are connected by the bonding wires B. In such a configuration, the plurality of memory dies MD and the controller dies CD are provided in one package. Meanwhile, the controller die CD may be provided in a package different from the memory die MD. Further, the plurality of memory dies MD and the controller dies CD may be connected to each other via through-electrodes or the like instead of the bonding wires B.

### Circuit Configuration of Memory Die MD

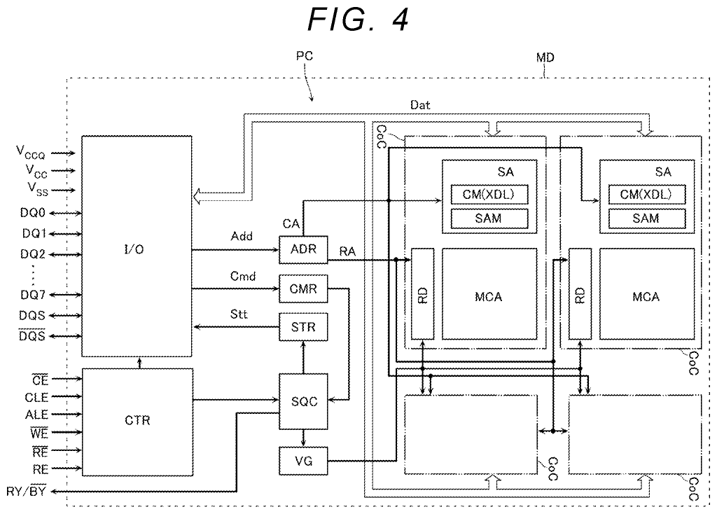

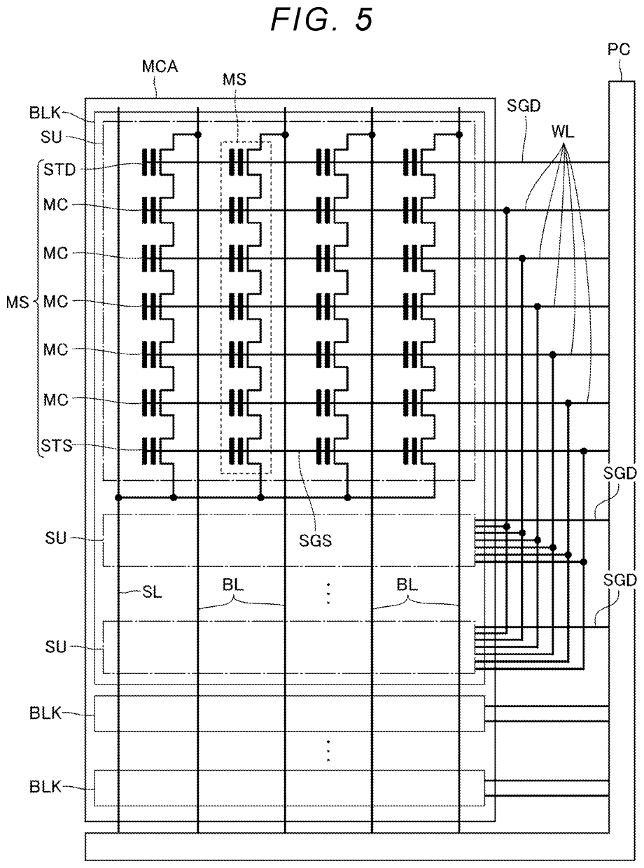

FIG. 4 is a schematic block diagram showing a configuration of the memory die MD according to the first embodiment. FIG. 5 is a schematic circuit diagram showing a configuration of a part of the memory die MD. For convenience of description, a part of the configuration is omitted in FIGS. 4 and 5.

FIG. 4 shows a plurality of control terminals and the like. The plurality of control terminals may be represented as control terminals corresponding to a high active signal (a positive logic signal), may be represented as control terminals corresponding to a low active signal (a negative logic signal), and may be represented as control terminals corresponding to both the high active signal and the low active signal. In FIG. 4, the reference sign of the control terminal corresponding to the low active signal includes an overline. In the present specification, the reference sign of the control terminal corresponding to the low active signal includes a slash (“/”). The illustration of FIG. 4 is an example, and the specific form may be adjusted as appropriate. For example, a part or all of high active signals may be set to the low active signals, or a part or all of low active signals may be set to the high active signals.

As shown in FIG. 4, the memory die MD includes a plurality of core circuits CoC, and peripheral circuits PC connected to the plurality of core circuits CoC.

### Configuration of Core Circuit CoC

Each core circuit CoC includes a memory cell array MCA, and a row decoder RD and a sense amplifier SA respectively connected to the memory cell array MCA.

### Configuration of Memory Cell Array MCA

As shown in FIG. 5, the memory cell array MCA includes a plurality of memory blocks BLK. Each of the plurality of memory blocks BLK includes a plurality of string units SU. Each of the plurality of string units SU includes a plurality of memory strings MS. One end of each of the plurality of memory strings MS is connected to the peripheral circuit PC via a bit line BL. In addition, the other end of each of the plurality of memory strings MS is connected to the peripheral circuit PC via a common source line SL.

The memory string MS includes a drain side select transistor STD that is connected in series between the bit line BL and the source line SL, a plurality of memory cells MC (memory cell transistors), and a source side select transistor STS. Hereinafter, the drain side select transistor STD and the source side select transistor STS may be simply referred to as a select transistor (STD, STS).

The memory cell MC is an electric field effect type transistor that includes a semiconductor layer, a gate insulating film, and a gate electrode. The semiconductor layer functions as a channel region. The gate insulating film includes a charge storage layer. A threshold voltage of the memory cell MC is changed according to a charge quantity in the charge storage layer. The memory cell MC usually stores the user data of one bit or a plurality of bits. The word line WL is connected to each of the gate electrodes of the plurality of memory cells MC corresponding to one memory string MS. Each of these word lines WL is commonly connected to all the memory strings MS in one memory block BLK.

The select transistors (STD, STS) are electric field effect type transistors including a semiconductor layer, a gate insulating film, and a gate electrode. The semiconductor layer functions as a channel region. A drain side select gate line SGD and a source side select gate line SGS are connected to each of the gate electrodes of the select transistors (STD, STS). The drain side select gate line SGD is provided corresponding to the string unit SU and commonly connected to all the memory strings MS in one string unit SU. The source side select gate line SGS is commonly connected to all the memory strings MS in the memory block BLK. Hereinafter, the drain side select gate line SGD and the source side select gate line SGS may be simply referred to as select gate lines (SGD, SGS).

### Configuration of Row Decoder RD

The row decoder RD includes, for example, a decode circuit and a switch circuit. The decode circuit decodes the row address RA stored in the address register ADR. The switch circuit causes the word line WL and the select gate lines (SGD, SGS) corresponding to the row address RA to be electrically connected to the corresponding voltage supply line in response to the output signal of the decode circuit.

### Configuration of Sense Amplifier SA

The sense amplifier SA (FIG. 4) includes a sense amplifier module SAM, and a cache memory CM (data register). The cache memory CM includes the latch circuit XDL.

The latch circuit XDL is connected to a latch circuit in the sense amplifier module SAM. The latch circuit XDL stores, for example, user data, which is written to the memory cell MC, or user data, which is read from the memory cell MC.

For example, a column decoder is connected to the cache memory CM. The column decoder decodes a column address CA that is stored in the address register ADR (FIG. 4), and selects the latch circuit XDL that corresponds to the column address CA.

The user data Dat, which is included in the plurality of latch circuits XDL, is sequentially transferred to the latch circuit in the sense amplifier module SAM at the time of the write operation. In addition, the user data Dat, which is included in the latch circuit in the sense amplifier module SAM, is sequentially transferred to the latch circuit XDL at the time of the read operation. In addition, the user data Dat, which is included in the latch circuit XDL, is sequentially transferred to the input/output control circuit I/O at the time of a data out operation.

### Configuration of Peripheral Circuit PC

The peripheral circuit PC includes, for example, as shown in FIG. 4, a voltage generation circuit VG and a sequencer SQC. In addition, the peripheral circuit PC includes an input/output control circuit I/O, a logic circuit CTR, an address register ADR, a command register CMR, and a status register STR.

The voltage generation circuit VG (FIG. 4) includes, for example, a step-down circuit such as a regulator, and a step-up circuit such as a charge pump circuit. The step-down circuit and the step-up circuit are respectively connected to the voltage supply lines that are supplied with a power supply voltage Vcc and a ground voltage Vss (FIG. 4). These voltage supply lines are connected to the pad electrodes P described with reference to FIGS. 2 and 3, for example. For example, the voltage generation circuit VG generates a plurality of operation voltages to be applied to the bit line BL, the source line SL, the word line WL, and the select gate lines (SGD, SGS) at the time of the read operation, the write operation, and the erasing operation with respect to the memory cell array MCA according to the control signal from the sequencer SQC, and simultaneously outputs the plurality of operation voltages to the plurality of voltage supply lines. The operation voltage, which is output from the voltage supply line, is appropriately adjusted according to the control signal from the sequencer SQC.

The sequencer SQC (FIG. 4) outputs an internal control signal to the row decoder RD, the sense amplifier module SAM, and the voltage generation circuit VG in accordance with command data Cmd stored in the command register CMR. The sequencer SQC outputs status data Stt, which indicates a state of the memory die MD, to the status register STR as appropriate.

The sequencer SQC generates a ready/busy signal and outputs the generated ready/busy signal to a terminal RY//BY. During a period (busy period) in which the terminal RY//BY is in the “L” state, an access to the memory die MD is basically prohibited. In addition, during a period (ready period) in which the terminal RY//BY is in the “H” state, the access to the memory die MD is permitted. The terminal RY//BY is implemented, for example, by the pad electrode P described with reference to FIGS. 2 and 3.

As shown in FIG. 4, the address register ADR is connected to the input/output control circuit I/O and stores the address data Add that is input from the input/output control circuit I/O. The address register ADR includes, for example, a plurality of 8-bit register rows. For example, when an internal operation such as the read operation, the write operation, or the erasing operation is executed, the register row stores the address data Add that corresponds to the internal operation being executed.

The address data Add includes, for example, the column address CA (FIG. 4) and the row address RA (FIG. 4). The row address RA includes, for example, a block address that specifies the memory block BLK (FIG. 5), a page address that specifies the string unit SU and the word line WL, a plane address that specifies a memory cell array MCA (plane), and a chip address that specifies the memory die MD.

The command register CMR is connected to the input/output control circuit I/O and stores the command data Cmd that is input from the input/output control circuit I/O. The command register CMR includes at least one set of 8-bit register rows, for example. When the command data Cmd is stored in the command register CMR, a control signal is transmitted to the sequencer SQC.

The status register STR is connected to the input/output control circuit I/O and stores the status data Stt to be output to the input/output control circuit I/O. The status register STR includes, for example, a plurality of 8-bit register rows. For example, when the internal operation such as the read operation, the write operation, or the erasing operation is executed, the register row stores the status data Stt that is related to the internal operation being executed. In addition, the register row stores ready/busy information of the memory cell array MCA, for example.

The input/output control circuit I/O (FIG. 4) includes a data signal input/output terminal DQn (n is a natural number of 0 to 7), data strobe signal input/output terminals DQS and /DQS, a shift register connected to the data signal input/output terminal DQn, a buffer circuit connected to the shift register, and power supply terminals VccQ, Vcc, and Vss.

Each of the data signal input/output terminal DQn and the data strobe signal input/output terminals DQS and /DQS is implemented by the pad electrode P described with reference to FIGS. 2 and 3, for example. The data, which is input via the data signal input/output terminal DQn, is input from the buffer circuit to the cache memory CM, the address register ADR, or the command register CMR in accordance with the internal control signal from the logic circuit CTR. In addition, the data, which is output via the data signal input/output terminal DQn, is input to the buffer circuit from the cache memory CM or the status register STR in accordance with the internal control signal from the logic circuit CTR.

The signals (for example, data strobe signals and complementary signals thereof), which are input via the data strobe signal input/output terminals DQS and /DQS, are used when the data is input via the data signal input/output terminal DQn. The data, which is input via the data signal input/output terminal DQn (n is a natural number of 0 to 7), is taken into the shift register in the input/output control circuit I/O at a timing of a rising edge of a voltage of the data strobe signal input/output terminal DQS (switching of the input signal) and a falling edge of a voltage of the data strobe signal input/output terminal /DQS (switching of the input signal), and at a timing of the falling edge of the voltage of the data strobe signal input/output terminal DQS (switching of the input signal) and the rising edge of the voltage of the data strobe signal input/output terminal /DQS (switching of the input signal). The power supply terminals VccQ, Vcc, and Vss are implemented, for example, by the pad electrode P described with reference to FIGS. 2 and 3. The power supply terminal VccQ and the power supply terminal Vss are connected to a shift register or the like provided in the input/output control circuit I/O (FIG. 4).

The logic circuit CTR (FIG. 4) includes a plurality of external control terminals /CE, CLE, ALE, /WE, /RE, and RE, and a logic circuit that is connected to the plurality of external control terminals /CE, CLE, ALE, /WE, /RE, and RE. The logic circuit CTR receives an external control signal from the controller die CD via the external control terminals /CE, CLE, ALE, /WE, /RE, and RE, and outputs the internal control signal to the input/output control circuit I/O in response to the reception.

Each of the external control terminals /CE, CLE, ALE, /WE, /RE, and RE is implemented, for example, by the pad electrode P described with reference to FIGS. 2 and 3.

### Structure of Memory Die MD

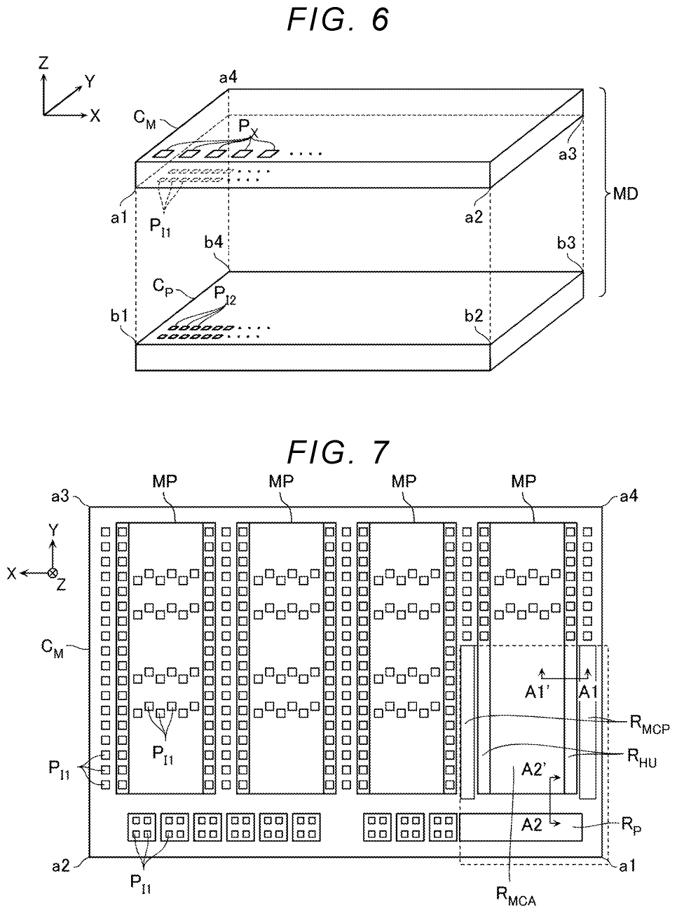

FIG. 6 is a schematic exploded perspective view showing a configuration of a semiconductor storage device according to the present embodiment. As shown in FIG. 6, the memory die MD includes a chip C_{M} on a memory cell array side and a chip C_{P} on a peripheral circuit side.

The plurality of external pad electrodes P_{X} are provided on the upper surface of the chip C_{M}. In addition, a plurality of first bonding electrodes P_{I1} are provided on the lower surface of the chip C_{M}. In addition, a plurality of second bonding electrodes P_{I2} are provided on the upper surface of the chip C_{P}. Hereinafter, regarding the chip C_{M}, a surface on which the plurality of first bonding electrodes P_{I1} are provided is referred to as a front surface, and a surface on which the plurality of external pad electrodes P_{X} are provided is referred to as a rear surface. In addition, regarding the chip C_{P}, a surface on which the plurality of second bonding electrodes P_{I2} are provided is referred to as a front surface, and a surface on the opposite side of the front surface is referred to as a rear surface. In the example shown in the drawing, the front surface of the chip C_{P} is provided above the rear surface of the chip C_{P}, and the rear surface of the chip C_{M} is provided above the front surface of the chip C_{M}.

The chip C_{M} and the chip C_{P} are disposed so that the front surface of the chip C_{M} faces the front surface of the chip C_{P}. The plurality of first bonding electrodes P_{I1} are provided respectively corresponding to the plurality of second bonding electrodes P_{I2}, and are arranged at positions bondable to the plurality of second bonding electrodes P_{I2}. The first bonding electrodes P_{I1} and the second bonding electrodes P_{I2} function as bonding electrodes for bonding the chip C_{M} and the chip C_{P} to each other and causing the chip C_{M} and the chip C_{P} to be electrically connected to each other. The external pad electrode P_{X} functions as the pad electrode P described with reference to FIGS. 2 and 3.

In the example of FIG. 6, corners a1, a2, a3, and a4 of the chip C_{M} correspond to corners b1, b2, b3, and b4 of the chip C_{P}, respectively.

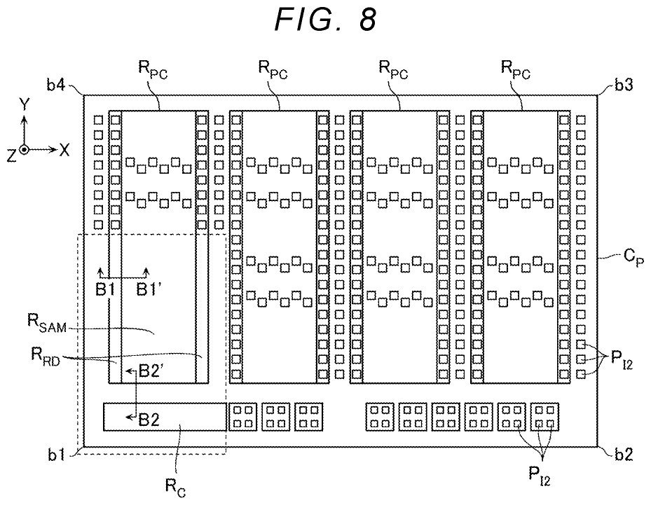

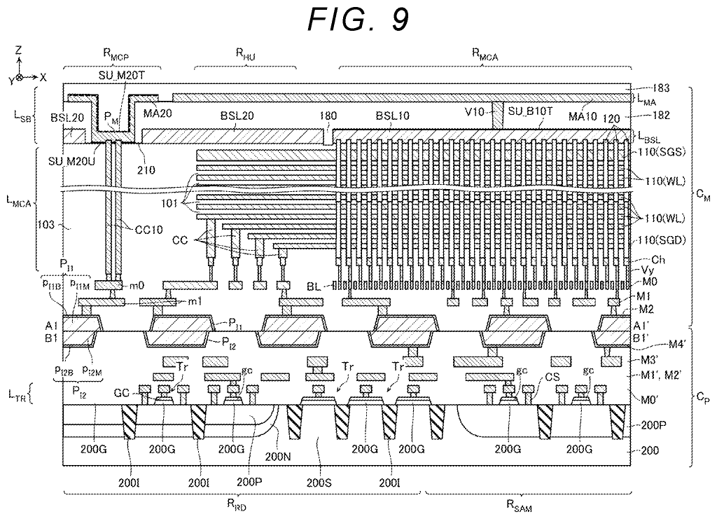

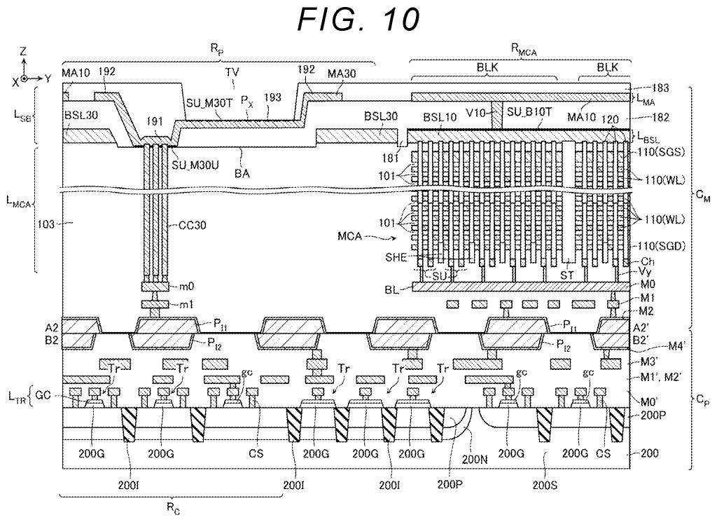

FIG. 7 is a schematic bottom view showing a configuration example of the chip C_{M}. A portion surrounded by a dotted line in the lower right of FIG. 7 shows a structure of the chip C_{M}, on an inner side with respect to a surface of the chip C_{M}, where the plurality of first bonding electrodes P_{I1} are provided. FIG. 8 is a schematic plan view showing a configuration example of the chip C_{P}. A portion surrounded by a dotted line in the lower left of FIG. 8 shows a structure of the chip C_{P}, on an inner side with respect to a surface of the chip C_{P}, where the plurality of second bonding electrodes P_{I2} are provided. FIG. 9 is a schematic sectional view corresponding to line A1-A1′ in FIG. 7 and line B1-B1′ in FIG. 8. FIG. 10 is a schematic sectional view corresponding to line A2-A2′ in FIG. 7 and line B2-B2′ in FIG. 8. FIGS. 9 and 10 show a cross section that is obtained by taking the structures shown in FIGS. 7 and 8 along each line and that is viewed in a direction of an arrow.

### Structure of Chip C_{M}

For example, as shown in FIG. 7, the chip C_{M} includes four memory planes MP arranged in the X direction. The memory plane MP includes, for example, a memory cell array region R_{MCA}, and hookup regions R_{HU} provided on one side and the other side in the X direction with respect to the memory cell array region R_{MCA}. In addition, the chip C_{M} includes, for example, a micropad region R_{MCP} provided between the adjacent memory planes MP, and the like, and a peripheral region R_{P} provided on one end side of the chip C_{M} in the Y direction.

For example, as shown in FIGS. 9 and 10, the chip C_{M} includes a base layer L_{SB}, a memory cell array layer L_{MCA} provided below the base layer L_{SB}, and a plurality of wiring layers M0, M1, and M2 provided below the memory cell array layer L_{M}CA.

The base layer L_{SB} includes the insulating layer 183 provided on the rear surface of the chip C_{M}, the wiring layer L_{MA} provided below the insulating layer 183, the insulating layer 182 provided below the wiring layer L_{MA}, and the wiring layer L_{BSL} provided below the insulating layer 182.

The insulating layer 183 is, for example, a passivation film made of polyimide or the like, or an insulating layer configured with silicon nitride (Si₃N₄), silicon oxide (SiO₂), or the like.

The wiring layer L_{MA} is a wiring layer including a plurality of conductive layers. The plurality of conductive layers provided in the wiring layer L_{MA} each contain a conductive material such as aluminum (Al). The wiring layer L_{MA} includes the wiring MA10 provided in the memory cell array region R_{MCA} and the hookup region R_{HU}, the electrode MA20 (FIG. 9) provided in the micropad region R_{MCP}, and the electrode MA30 (FIG. 10) provided in the peripheral region R_{P}.

The wiring MA10 is electrically connected to a conductive layer BSL10 described below, for example, via a plurality of contacts V10 and the like. The wiring MA10 functions as, for example, an auxiliary wiring of a conductive layer BSL10 that functions as a source line SL (FIG. 5). The wiring MA10 contains a conductive material such as aluminum (Al).

The electrode MA20 (FIG. 9) is electrically connected to the configuration in the chip C_{P} via, for example, a plurality of contacts CC10 provided in the insulating layer 103 made of silicon oxide (SiO₂) or the like.

A surface SU_M20T (FIG. 9), which is a surface of the electrode MA20 (FIG. 9) on a side opposite to a semiconductor substrate 200, is entirely covered with the insulating layer 183.

The electrode MA20 functions as a micropad electrode P_{M}. The electrode MA20 contains a conductive material such as aluminum (Al).

The micropad electrode P_{M} is a pad electrode for evaluating and analyzing a circuit, wiring, a transistor, and the like inside the memory die MD. Unlike the external pad electrode P_{X} (FIG. 6), the micropad electrode P_{M} is not connected to the bonding wire B (FIGS. 2 and 3) for external connection.

The electrode MA30 (FIG. 10) is electrically connected to the configuration in the chip C_{P} via, for example, a plurality of contacts CC30 provided in the insulating layer 103.

A surface SU_M30T, which is a surface of the electrode MA30 (FIG. 10) on a side opposite to a semiconductor substrate 200, includes a pad electrode region 193 not covered with the insulating layer 183.

The pad electrode region 193 of the electrode MA30 functions as an external pad electrode P_{X}. The electrode MA30 contains a conductive material such as aluminum (Al).

As described with reference to FIGS. 2 and 3, the external pad electrode P_{X} is connected to the bonding wire B (FIGS. 2 and 3) for external connection.

The insulating layer 182 is, for example, an insulating layer configured with silicon nitride (Si₃N₄) and silicon oxide (SiO₂).

The wiring layer L_{BSL} is a wiring layer including a plurality of conductive layers. Each of the plurality of conductive layers provided in the wiring layer L_{BSL} includes, for example, a semiconductor layer made of polycrystalline silicon (Si) or the like into which an N-type impurity such as phosphorus (P) or a P-type impurity such as boron (B) is injected. The wiring layer L_{BSL} includes the conductive layer BSL10 provided in the memory cell array region R_{MCA}, the conductive layer BSL20 (FIG. 9) provided in the hookup region R_{HU} and the micropad region R_{MCP}, and the conductive layer BSL30 (FIG. 10) provided in the peripheral region R_{P}.

The conductive layer BSL10 is connected to upper end portions of a plurality of the semiconductor pillars 120 described below, for example, as shown in FIGS. 9 and 10. The conductive layer BSL10 may be provided, for example, over a region overlapping the plurality of semiconductor pillars 120 as viewed from the Z direction.

The conductive layer BSL10 functions as the source line SL (FIG. 5). The conductive layer BSL10 includes, for example, a semiconductor layer made of polycrystalline silicon (Si) or the like into which an N-type impurity such as phosphorus (P) or a P-type impurity such as boron (B) is injected.

The conductive layer BSL20 has an opening 210 (FIG. 9). For example, a part of the electrode MA20 is provided inside the opening 210. The conductive layer BSL20 is not connected to the configuration such as the plurality of semiconductor pillars 120, the contact CC10, and the like, which are provided in the memory cell array layer L_{MCA}. The conductive layer BSL20 includes, for example, a semiconductor layer made of polycrystalline silicon (Si) or the like into which an N-type impurity such as phosphorus (P) or a P-type impurity such as boron (B) is injected.

A slit 180 (FIG. 9) is provided between the conductive layer BSL20 and the conductive layer BSL10, and a part of the insulating layer 182 is provided in the slit 180. The conductive layer BSL20 and the conductive layer BSL10 are electrically insulated from each other.

The conductive layer BSL30 has an opening BA (FIG. 10). For example, a part of the electrode MA30 is provided inside the opening BA. The conductive layer BSL30 is not connected to the configuration such as the plurality of semiconductor pillars 120, the contact CC30, and the like, which are provided in the memory cell array layer L_{MCA}. The conductive layer BSL30 includes, for example, a semiconductor layer made of polycrystalline silicon (Si) or the like into which an N-type impurity such as phosphorus (P) or a P-type impurity such as boron (B) is injected.

A slit 181 (FIG. 10) is provided between the conductive layer BSL30 and the conductive layer BSL10, and a part of the insulating layer 182 is provided in the slit 181. The conductive layer BSL30 and the conductive layer BSL10 are electrically insulated from each other.

A surface SU_M20U (FIG. 9), which is at least a part of a surface of the electrode MA20 (FIG. 9) on the semiconductor substrate 200 side, is closer to the semiconductor substrate 200 than the surface SU_B10T (FIGS. 9 and 10), which is a surface of the conductive layer BSL10 on a side opposite to the semiconductor substrate 200, in the Z direction.

A surface SU_M30U (FIG. 10), which is at least a part of a surface of the electrode MA30 (FIG. 10) on the semiconductor substrate 200 side, is closer to the semiconductor substrate 200 than the surface SU_B10T (FIGS. 9 and 10) in the Z direction.

A plurality of memory blocks BLK arranged in the Y direction are provided in the memory cell array region R_{MCA} (FIG. 10) of the memory cell array layer L_{MCA}. The memory block BLK includes a plurality of string units SU arranged in the Y direction. An inter-block insulating layer ST made of silicon oxide (SiO₂) or the like is provided between two memory blocks BLK adjacent to each other in the Y direction. An inter-string unit insulating layer SHE, which is made of silicon oxide (SiO₂) or the like is provided between two string units SU adjacent to each other in the Y direction.

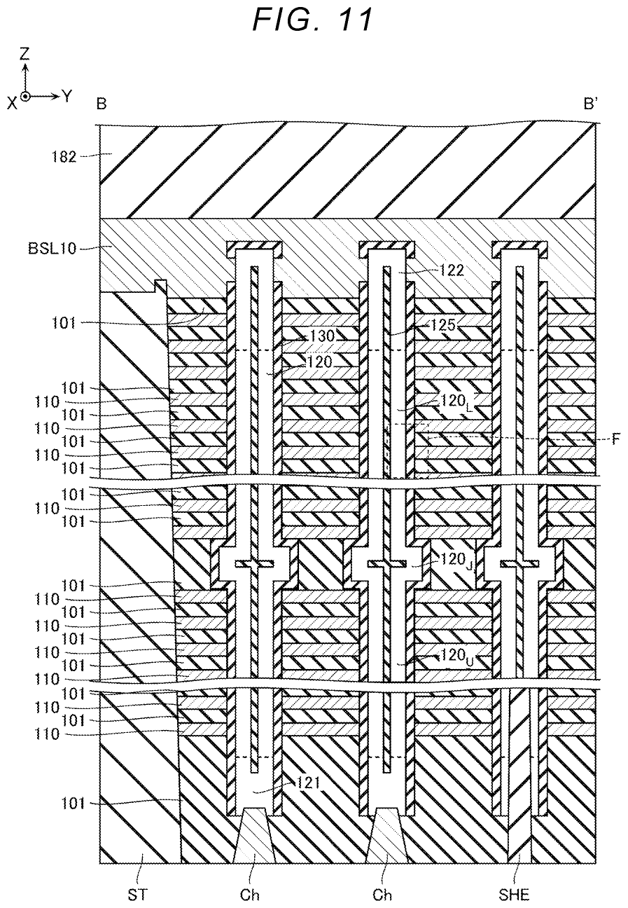

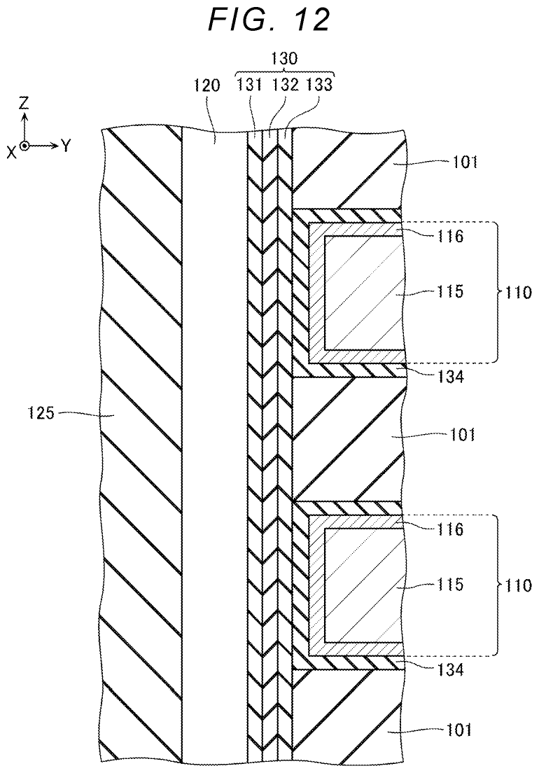

FIG. 11 is a schematic sectional view showing a memory cell array region R_{MCA} in an enlarged manner. FIG. 12 is a schematic enlarged view of a portion indicated by F in FIG. 11. Although FIG. 12 shows a YZ cross section, a structure similar to that in FIG. 12 is observed even when a cross section other than the YZ cross section (for example, an XZ cross section) along the central axis of a semiconductor pillar 120 is observed.

For example, as shown in FIG. 11, the memory block BLK includes a plurality of conductive layers 110 arranged in the Z direction, a plurality of semiconductor pillars 120 extending in the Z direction, and a plurality of gate insulating films 130 respectively provided between the plurality of conductive layers 110 and the plurality of semiconductor pillars 120.

The conductive layer 110 is a substantially plate-shaped conductive layer extending in the X direction. As shown in FIG. 12, the conductive layer 110 may include a stacked film including a barrier conductive film 116 made of titanium nitride (TiN) or the like and a metal film 115 made of tungsten (W) or the like. An insulating metal oxide film 134 made of alumina (AlO) or the like may be provided at a position covering an outer periphery of the barrier conductive film 116. In addition, the conductive layer 110 may contain, for example, polycrystalline silicon containing impurities such as phosphorus (P) or boron (B). Insulating layers 101 made of silicon oxide (SiO₂) or the like are provided between the plurality of conductive layers 110 arranged in the Z direction.

As shown in FIG. 11, the above-described conductive layer BSL10 is provided above the conductive layer 110. The conductive layer BSL10 is connected to an outer peripheral surface of an upper end portion of the semiconductor pillar 120. The insulating layer 101 made of silicon oxide (SiO₂) or the like is provided between the conductive layer 110 and the conductive layer BSL10. For example, the conductive layer BSL10, which functions as the source line SL (FIG. 5), is commonly provided for all the memory blocks BLK provided in the memory cell array region R_{MCA} (FIGS. 9 and 10), and is electrically independent for each memory cell array MCA.

Among the plurality of conductive layers 110, one or a plurality of conductive layers 110 positioned on the uppermost layer function as the source side select gate line SGS (FIG. 5) and the gate electrodes of the plurality of source side select transistors STS connected to the source side select gate line SGS. The plurality of conductive layers 110 are electrically independent for each memory block BLK.

A plurality of conductive layers 110 positioned below the above-described conductive layers 110 function as the word line WL (FIG. 5) and the gate electrodes of the plurality of memory cells MC (FIG. 5) connected to the word line WL. The plurality of conductive layers 110 are electrically independent for each memory block BLK.

One or a plurality of conductive layers 110 positioned below the above-described conductive layers 110 function as the drain side select gate line SGD and the gate electrodes of the plurality of drain side select transistors STD (FIG. 5) connected to the drain side select gate line SGD. Widths of the plurality of conductive layers 110 in the Y direction are smaller than those of the other conductive layers 110. An inter-string unit insulating layer SHE is provided between two conductive layers 110 adjacent to each other in the Y direction. Each of the plurality of conductive layers 110 is electrically independent for each string unit SU.

For example, as shown in FIGS. 9 and 10, the semiconductor pillars 120 are arranged in the X direction and the Y direction in a predetermined pattern. The semiconductor pillars 120 function as channel regions of the plurality of memory cells MC and select transistors (STD, STS) in one memory string MS (FIG. 5). The semiconductor pillar 120 is a semiconductor layer made of polycrystalline silicon (Si) or the like, for example. An insulating layer 125 (FIG. 11) made of silicon oxide or the like is provided at a center portion of the semiconductor pillar 120.

As shown in FIG. 11, the semiconductor pillar 120 includes a semiconductor region 120_{L}, and a semiconductor region 120_{U} provided below the semiconductor region 120_{L}.

The semiconductor pillar 120 includes a semiconductor region 120₁ connected to a lower end of the semiconductor region 120_{L} and an upper end of the semiconductor region 120_{U}, an impurity region 122 connected to an upper end of the semiconductor region 120_{L}, and an impurity region 121 connected to a lower end of the semiconductor region 120_{U}.

The semiconductor region 120_{L} and the semiconductor region 120_{U} are substantially cylindrical-shaped regions extending in the Z direction. Each of outer peripheral surfaces of the semiconductor region 120_{L} and the semiconductor region 120_{U} is surrounded by the plurality of conductive layers 110, which are provided in the memory cell array layer L_{MCA}, and faces the plurality of conductive layers 110.

The impurity region 121 contains, for example, N-type impurities such as phosphorus (P). In the example of FIG. 11, a boundary line between the lower end portion of the semiconductor region 120_{U} and the upper end portion of the impurity region 121 is shown by a broken line. The impurity region 121 is connected to the bit line BL via a contact Ch and a contact Vy (FIGS. 9 and 10).

The impurity region 122 contains, for example, N-type impurities such as phosphorus (P) or P-type impurities such as boron (B). In the example of FIG. 11, a boundary line between the upper end portion of the semiconductor region 120_{L} and the lower end portion of the impurity region 122 is shown by a broken line. The impurity region 122 is connected to the conductive layer BSL10.

The gate insulating film 130 has a cylindrical shape that covers the outer peripheral surface of the semiconductor pillar 120. For example, as shown in FIG. 12, the gate insulating film 130 includes a tunnel insulating film 131, a charge storage layer 132, and a block insulating film 133, which are stacked between the semiconductor pillar 120 and the conductive layer 110. The tunnel insulating film 131 and the block insulating film 133 are insulating films made of silicon oxide (SiO₂) or the like, for example. The charge storage layer 132 is made of, for example, silicon nitride (Si₃N₄) or the like, and includes a film that is capable of storing charges. The tunnel insulating film 131, the charge storage layer 132, and the block insulating film 133 have a substantially cylindrical shape, and extend in the Z direction along the outer peripheral surface of the semiconductor pillar 120.

FIG. 12 shows an example in which the gate insulating film 130 includes the charge storage layer 132 containing silicon nitride or the like. Meanwhile, the gate insulating film 130 may include, for example, a floating gate made of polycrystalline silicon containing N-type or P-type impurities.

A plurality of contacts CC are provided in a hookup region R_{HU} of the memory cell array layer L_{MCA}, for example, as shown in FIG. 9. The plurality of contacts CC extend in the Z direction and are each connected to the conductive layer 110 at the upper ends of the contacts CC. These plurality of contacts CC are connected to the configuration in the chip C_{P} via the wiring m0 and the wiring ml in the wiring layers M0 and M1 and the first bonding electrode P_{I1} in the wiring layer M2. The contact CC may include, for example, a stacked film of a barrier conductive film made of titanium nitride (TiN) or the like and a metal film made of tungsten (W) or the like.

A plurality of contacts CC10 (FIG. 9) are provided in the micropad region R_{MCP} of the memory cell array layer L_{MCA}. The contact CC10 is connected to the electrode MA20 at the upper end thereof as described above, and is connected to wiring m0 and the like described below at the lower end thereof.

A plurality of contacts CC30 (FIG. 10) are provided in a peripheral region R_{P} of the memory cell array layer L_{MCA}. The contact CC30 is connected to the connection portion 191 of the electrode MA30 at the upper end thereof as described above, and is connected to wiring m0 and the like described below at the lower end thereof.

For example, as shown in FIGS. 9 and 10, the plurality of pieces of wirings provided in the wiring layers M0, M1, and M2 are electrically connected to at least one of the configuration in the memory cell array layer L_{MCA} and the configuration in the chip C_{P}, for example.

The wiring layer M0 includes a plurality of pieces of wirings m0. The plurality of pieces of wirings m0 may include, for example, a stacked film of a barrier conductive film made of titanium nitride (TiN), tantalum nitride (TaN), or the like and a metal film made of copper (Cu) or the like. Some of the plurality of pieces of wirings m0 function as the bit lines BL (FIG. 5). For example, the bit lines BL are arranged in the X direction and extend in the Y direction as shown in FIGS. 9 and 10. In addition, the plurality of bit lines BL are connected to one semiconductor pillar 120 provided in each string unit SU, respectively.

The wiring layer M1 includes a plurality of pieces of wirings ml. The plurality of pieces of wirings ml may include, for example, a stacked film of a barrier conductive film made of titanium nitride (TiN), tantalum nitride (TaN), or the like and a metal film made of copper (Cu) or the like.

The wiring layer M2 includes a plurality of first bonding electrodes P_{I1}. The plurality of first bonding electrodes P_{I1} may include, for example, a stacked film of a barrier conductive film p_{I1B} made of titanium nitride (TiN), tantalum nitride (TaN), or the like and a metal film p_{I1M} made of copper (Cu) or the like.

### Structure of Chip C_{P}

The chip C_{P} includes, for example, four peripheral circuit regions R_{PC} arranged in the X direction corresponding to the memory plane MP, as shown in FIG. 8. The peripheral circuit region R_{PC} includes a sense amplifier module region R_{SAM} provided in a part of the region facing the memory cell array region R_{MCA}, and a row decoder region R_{RD} provided in the region facing the hookup region R_{HU}. In addition, the chip C_{P} includes a circuit region R_{C} provided in a region facing the peripheral region R_{P}.

In addition, for example, as shown in FIGS. 9 and 10, the chip C_{P} includes a semiconductor substrate 200, a transistor layer L_{TR} provided above the semiconductor substrate 200, and a plurality of wiring layers M0′, M1′, M2′, M3′, and M4′ provided above the transistor layer L_{TR}.

The semiconductor substrate 200 is a semiconductor substrate configured with P-type silicon (Si) containing P-type impurities such as boron (B), for example. For example, as shown in FIGS. 9 and 10, an N-type well region 200N containing N-type impurities such as phosphorus (P), a P-type well region 200P containing P-type impurities such as boron (B), a semiconductor substrate region 200S in which the N-type well region 200N and the P-type well region 200P are not provided, and an insulating region 2001 are provided on the surface of the semiconductor substrate 200. The N-type well region 200N, the P-type well region 200P, and the semiconductor substrate region 200S function as a part of the plurality of transistors Tr, the plurality of capacitors, and the like that constitute the peripheral circuit PC, respectively.

For example, as shown in FIGS. 9 and 10, a wiring layer GC is provided on the upper surface of the semiconductor substrate 200 via an insulating layer 200G. The wiring layer GC includes a plurality of electrodes gc that face a surface of the semiconductor substrate 200. Each of the regions of the semiconductor substrate 200 and the plurality of electrodes gc, which are provided in the wiring layer GC, is connected to a contact CS.

The N-type well region 200N, the P-type well region 200P, and the semiconductor substrate region 200S of the semiconductor substrate 200 function as channel regions of a plurality of transistors Tr, one electrode of a plurality of capacitors, and the like that constitute the peripheral circuit PC, respectively.

The plurality of electrodes gc provided in the wiring layer GC function as gate electrodes of a plurality of transistors Tr, other electrodes of a plurality of capacitors, and the like that constitute the peripheral circuit PC, respectively.

The contact CS extends in the Z direction and is connected to the upper surface of the semiconductor substrate 200 or the upper surface of the electrode gc at the lower end of the contact CS. A high-concentration impurity region containing N-type impurities or P-type impurities (not shown) is provided at a portion at which the contact CS and the semiconductor substrate 200 are connected to each other. The contact CS may include, for example, a stacked film of a barrier conductive film made of titanium nitride (TiN) or the like and a metal film made of tungsten (W) or the like.

The wiring layer M0′ is provided above the transistor layer L_{TR}. The wiring layer M0′ is, for example, a wiring layer containing a conductive material such as tungsten (W). The wiring layer M1′ is provided above the wiring layer M0′. The wiring layer M1′ is, for example, a wiring layer containing a conductive material such as copper (Cu). The wiring layer M2′ is provided above the wiring layer M1′, although not shown in FIGS. 9 and 10. The wiring layer M2′ is, for example, a wiring layer containing a conductive material such as copper (Cu). The wiring layer M3′ is, for example, a wiring layer containing a conductive material such as copper (Cu) or aluminum (Al). The wiring layer M4′ is, for example, a wiring layer containing a conductive material such as copper (Cu), and includes a plurality of second bonding electrodes P_{I2}. The plurality of second bonding electrodes P_{I2} may include, for example, a stacked film of a barrier conductive film p_{I2B} made of titanium nitride (TiN) or the like and a metal film p_{I2M} made of copper (Cu) or the like.

Here, if metal films p_{I1M} and p_{I2M} made of copper (Cu) or the like are used for the first bonding electrode P_{I1} and the second bonding electrode P_{I2}, the metal film p_{I1M} and the metal film p_{I2M} are integrated with each other, and it is difficult to confirm the boundary between the metal film p_{I1M} and the metal film p_{I2M}. It is noted that the bonding structure can be confirmed by the distortion of the shape in which the first bonding electrode P_{I1} and the second bonding electrode P_{I2} are bonded to each other due to the positional deviation in bonding, and by the positional deviation (occurrence of a discontinuous portion on the side surface) of the barrier conductive films p_{I1B} and P_{I2B}. In addition, when the first bonding electrode P_{I1} and the second bonding electrode P_{I2} are formed by the damascene method, each of the side surfaces has a tapered shape. Therefore, for the shape of the cross section along the Z direction at the portion where the first bonding electrode P_{I1} and the second bonding electrode P_{I2} are bonded to each other, a side wall is not linear and has a non-rectangular shape. In addition, when the first bonding electrode P_{I1} and the second bonding electrode P_{I2} are bonded to each other, a structure in which the bottom surface, the side surface, and the upper surface of each Cu forming these electrodes are covered with the barrier metal. To the contrary, in a wiring layer using general Cu, an insulating layer (SiN, SiCN, or the like) having an antioxidant function of Cu is provided on an upper surface of Cu, and a barrier metal is not provided. Therefore, it is possible to distinguish the electrodes from a general wiring layer even when the positional deviation in bonding does not occur.

### Arrangement Example of Micropad Region R_{MCP}

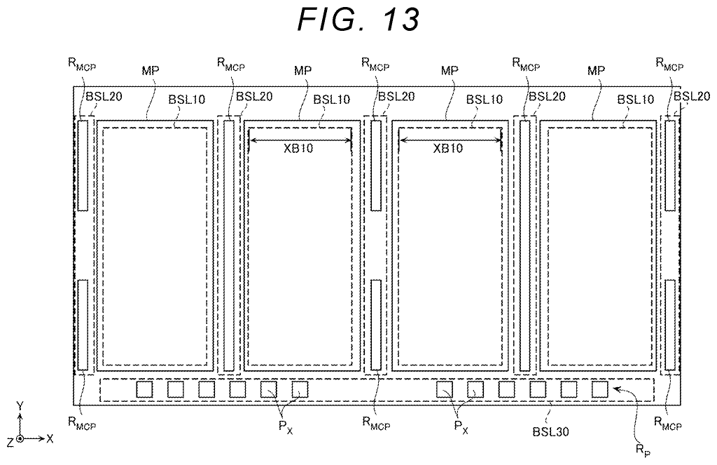

Next, an arrangement example of the micropad region R_{MCP} will be described with reference to FIG. 13. FIG. 13 is a top view showing an arrangement example of the micropad region R_{MCP} in the chip C_{M}.

The micropad region R_{MCP} is provided, for example, between the adjacent memory plane MP and memory plane MP, as shown in FIG. 13. The micropad electrodes P_{M} provided in such a micropad region R_{MCP} are provided between the memory plane MP and the memory plane MP that are arranged in the X direction.

In addition, the plurality of micropad regions R_{MCP} may be arranged in the Y direction between the memory plane MP and the memory plane MP that are arranged in the X direction. For example, in FIG. 13, two micropad regions R_{MCP} arranged in the Y direction are shown between the second memory plane MP and the third memory plane MP counted from the negative side in the X direction.

In addition, the micropad region R_{MCP} may be provided, for example, in the vicinity of both end sides of the chip C_{M} in the X direction, as shown in FIG. 13. For example, in FIG. 13, two micropad regions R_{MCP} arranged in the Y direction are provided at the negative side end of the chip C_{M} in the X direction. In addition, two micropad regions R_{MCP} arranged in the Y direction are provided at the positive side end of the chip C_{M} in the X direction.

In the example shown in FIG. 13, the conductive layers BSL10 are arranged in the X direction, respectively corresponding to the plurality of memory planes MP arranged in the X direction. The conductive layer BSL20 is provided between the memory plane MP and the memory plane MP that are arranged in the X direction, in correspondence with one or a plurality of the micropad regions R_{MCP}. The conductive layer BSL20 is separated from the conductive layer BSL10 in the X direction.

A plurality of the conductive layers BSL20 may be arranged, for example, between the adjacent conductive layers BSL10. Even in such a case, the slits 180 are formed between the plurality of conductive layers BSL20 and the conductive layer BSL10, and the conductive layer BSL10 is separated from the plurality of conductive layers BSL20.

In the example shown in FIG. 13, the peripheral region R_{P} is provided at a position separated from the memory plane MP and the micropad region R_{MCP} in the Y direction. In addition, in the example shown in FIG. 13, the conductive layer BSL30 is provided corresponding to the peripheral region R_{P}.

### Detailed Configuration Example of Micropad Region R_{MCP}

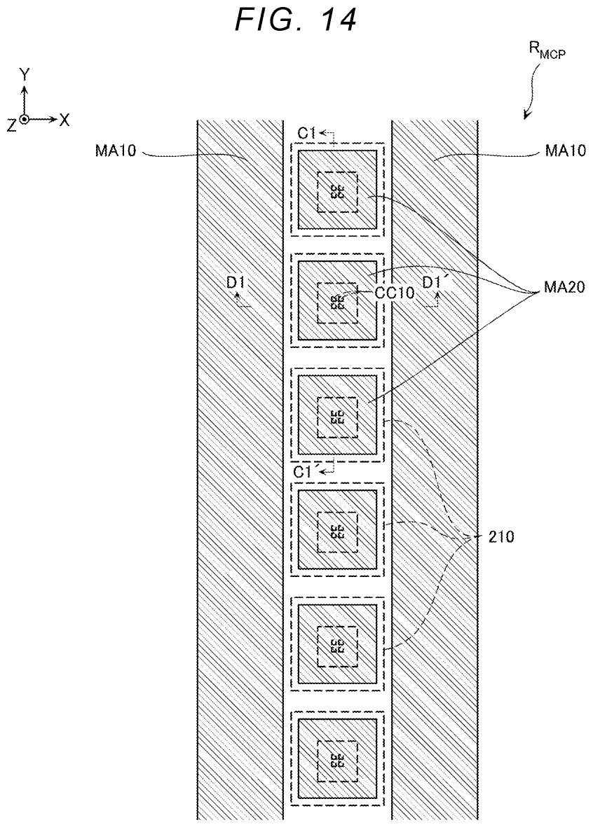

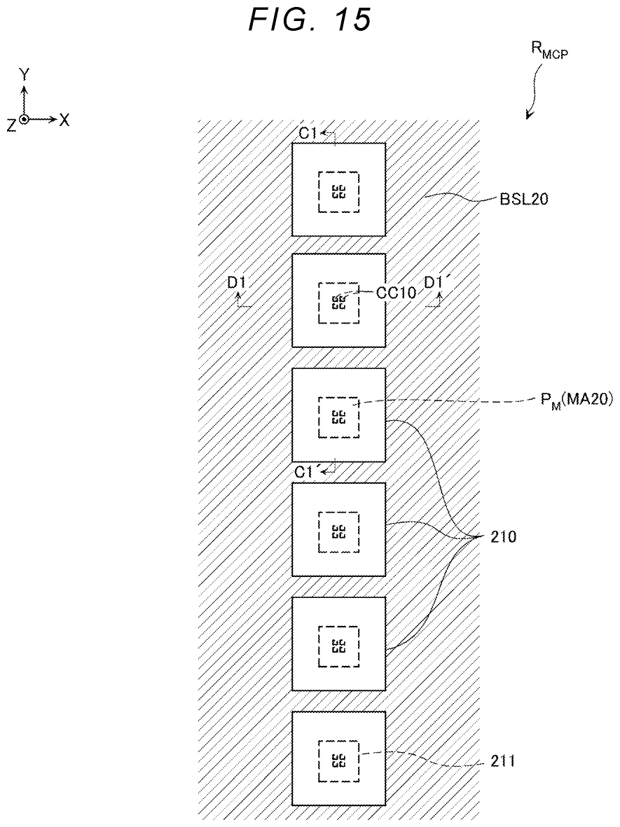

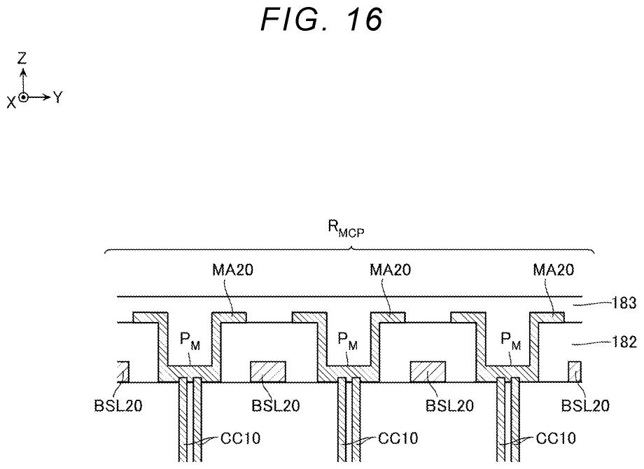

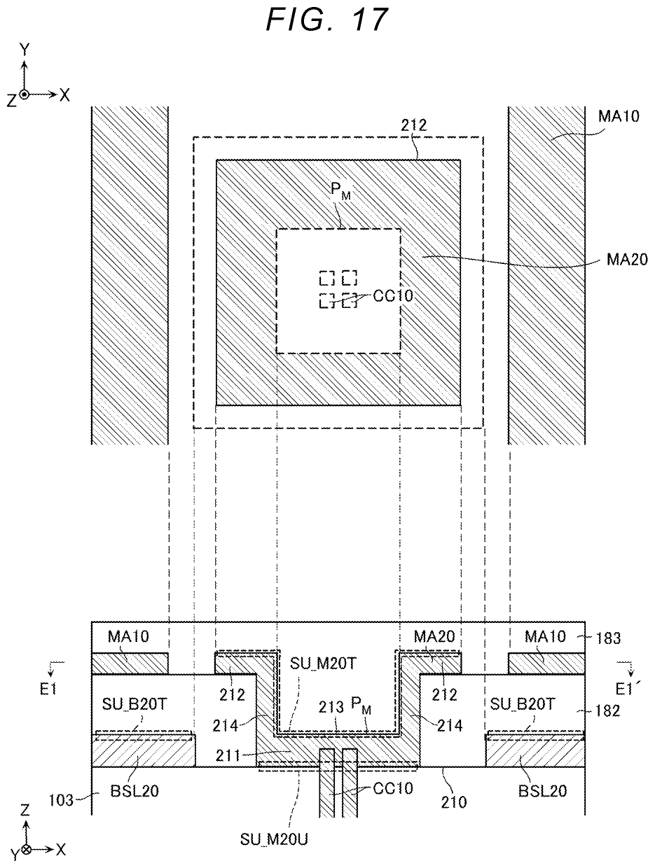

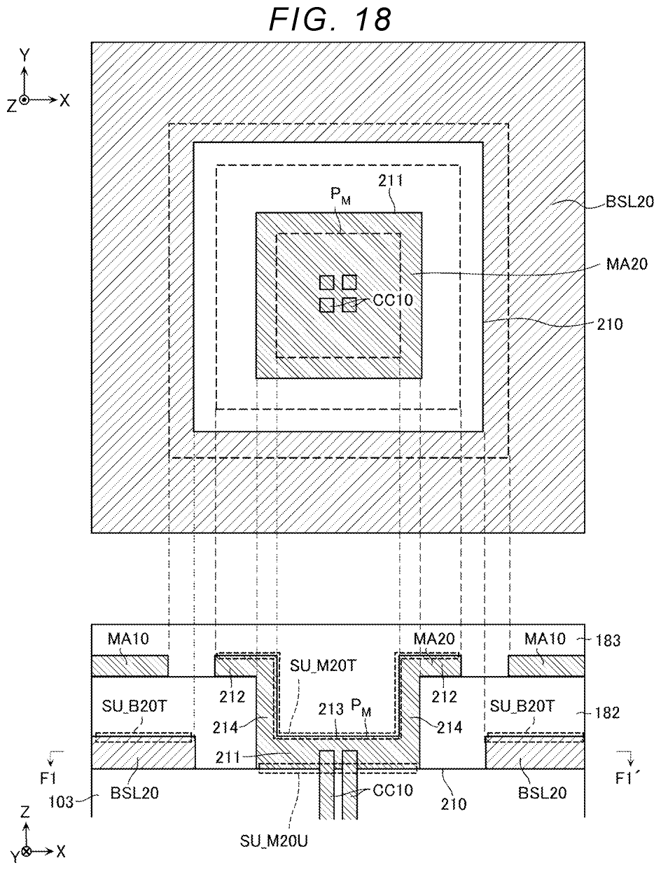

Next, a detailed configuration example of the micropad region R_{MCP} will be described with reference to FIGS. 9, and 14 to 18. FIG. 14 is a top view of the wiring layer L_{MA} in the micropad region R_{MCP} as viewed from the positive side in the Z direction. FIG. 15 is a top view of the wiring layer L_{BSL} in the micropad region R_{MCP} as viewed from the positive side in the Z direction. FIGS. 14 and 15 show a part of the micropad region R_{MCP} shown in FIG. 13 in an enlarged manner. FIG. 16 is a sectional view taken along line C1-C1′ in FIG. 14 and FIG. 15 and viewed from the arrow direction (positive side in the X direction). The lower diagram of FIG. 17 and the lower diagram of FIG. 18 are sectional views taken along line D1-D1′ in FIG. 14 and FIG. 15 and viewed from the arrow direction (negative side in the Y direction). The upper diagram of FIG. 17 is a sectional view taken along line E1-E1′ in the lower diagram of FIG. 17 and viewed from the arrow direction (positive side in the Z direction). The upper diagram of FIG. 18 is a sectional view taken along line F1-F1′ in the lower diagram of FIG. 18 and viewed from the arrow direction (positive side in the Z direction).

A plurality of electrodes MA20 are arranged in the Y direction, for example, as shown in FIGS. 14 and 16. The electrode MA20 is formed as an isolated pattern separated from the wiring MA10 adjacent to the positive side and negative side in the X direction, as viewed from the positive side in the Z direction (FIG. 14). The electrode MA20 has, for example, a substantially quadrangular shape as viewed from the positive side in the Z direction.

For example, a part of the insulating layer 182 and a part of the insulating layer 183 are provided between the electrodes MA20 adjacent to each other in the Y direction and between the electrode MA20 and the wiring MA10 (FIGS. 9 and 16).

The conductive layer BSL20 is provided with a plurality of the openings 210 arranged in the Y direction, for example, as shown in FIG. 15. The opening 210 has, for example, a substantially quadrangular shape as viewed from the positive side in the Z direction. The opening 210 is formed in a size that can accommodate, for example, a connection portion 211 which is a part of the electrode MA20.

For example, as shown in the lower diagram of FIG. 17, the electrode MA20 includes a connection portion 211 connected to the upper end of the contact CC10, and a peripheral edge portion 212 provided around the connection portion 211 as viewed from the Z direction. In addition, a pad electrode region 213 functioning as a micropad electrode P_{M} is provided on the upper surface of the connection portion 211. In addition, the electrode MA20 includes a side wall portion 214 provided between the connection portion 211 and the peripheral edge portion 212.

The connection portion 211 is formed on the upper surface of the insulating layer 103 (lower diagram of FIG. 17). The connection portion 211 is connected to the contact CC10, for example, in the vicinity of the center in the X direction and the Y direction, as shown in the upper diagram of FIG. 18. The connection portion 211 has, for example, a substantially quadrangular shape extending in the X direction and the Y direction. The upper surface of the connection portion 211 is covered with the insulating layer 183 and is not exposed to the outside of the memory die MD.

The peripheral edge portion 212 is formed on the upper surface of the insulating layer 182, similarly to the wiring MA10 (lower diagram of FIG. 17). The peripheral edge portion 212 is provided, for example, above the upper surface of the conductive layer BSL20, that is, at a position far from the semiconductor substrate 200 (FIG. 9) (lower diagram of FIG. 17). The peripheral edge portion 212 is provided at a position that does not overlap the connection portion 211 as viewed from the positive side in the Z direction. The peripheral edge portion 212 includes a portion extending in the X direction or the Y direction (upper diagram of FIG. 17). The peripheral edge portion 212 is connected to the side wall portion 214 at an inner peripheral portion thereof (lower diagram of FIG. 17). The upper surface of the peripheral edge portion 212 is covered with the insulating layer 183 and is not exposed to the outside of the memory die MD.

The side wall portion 214 extends in a direction away from the semiconductor substrate 200 (FIG. 9), for example, toward a positive side in the Z direction (lower diagram of FIG. 17). The side wall portion 214 is formed on, for example, an inner side surface of the opening provided in the insulating layer 182. The inner peripheral surface of the side wall portion 214 is covered with the insulating layer 183 and is not exposed to the outside of the memory die MD.

In the examples shown in FIGS. 17 and 18, the connection portion 211, the peripheral edge portion 212, the pad electrode region 213, and the side wall portion 214 are formed inside the opening 210 as viewed from the positive side in the Z direction. Meanwhile, for example, a part of the peripheral edge portion 212 may be formed from the inside to the outside of the opening 210 as viewed from the positive side in the Z direction.

A surface SU_M20U (FIG. 17), which is at least a part of a surface of the electrode MA20 (FIG. 17) on the semiconductor substrate 200 side, is closer to the semiconductor substrate 200 than the surface SU_B20T (FIG. 17), which is a surface of the conductive layer BSL20 on a side opposite to the semiconductor substrate 200, in the Z direction.

### Detailed Configuration Example of Peripheral Region R_{P}

Next, a detailed configuration example of the peripheral region R_{P} will be described with reference to FIGS. 10 and 13.

The electrode MA30 is formed as an isolated pattern separated from the wiring MA10 adjacent to the positive side in the Y direction (FIG. 10). A plurality of electrodes MA30 are arranged in the X direction, for example, corresponding to the plurality of external pad electrodes P_{X} arranged in the X direction shown in FIG. 13.

For example, a part of the insulating layer 182 and a part of the insulating layer 183 are provided between the electrode MA30 and the wiring MA10 (FIG. 10).

The conductive layer BSL30 is provided with a plurality of the openings BA arranged in the X direction, for example. The opening BA is formed in a size that can accommodate, for example, a connection portion 191 which is a part of the electrode MA30.

For example, as shown in FIG. 10, the electrode MA30 includes a connection portion 191 connected to the upper end of the contact CC30, a pad electrode region 193 forming the external pad electrode P_{X}, and a peripheral edge portion 192 provided around them.

The connection portion 191 is formed on the upper surface of the insulating layer 103 (FIG. 10). The connection portion 191 is connected to the contact CC30, for example, in the vicinity of the center in the X direction and the Y direction, as shown in FIG. 10. The connection portion 191 has, for example, a substantially quadrangular shape extending in the X direction and the Y direction. The upper surface of the connection portion 191 is covered with the insulating layer 183 and is not exposed to the outside of the memory die MD.

The peripheral edge portion 192 is formed on the upper surface of the insulating layer 182, similarly to the wiring MA10 (FIG. 10). The peripheral edge portion 192 is provided, for example, above the upper surface of the conductive layer BSL20, that is, at a position far from the semiconductor substrate 200 (FIG. 10). The peripheral edge portion 192 is provided at a position that does not overlap the connection portion 191 as viewed from the positive side in the Z direction. The upper surface of the peripheral edge portion 192 is covered with the insulating layer 183 and is not exposed to the outside of the memory die MD.

The pad electrode region 193 (FIG. 10) is provided at a position different from the connection portion 211, for example, as viewed from the positive side in the Z direction. A position of the pad electrode region 193 in the Z direction is, for example, between the connection portion 191 and the peripheral edge portion 192. The upper surface of the pad electrode region 193 is exposed to the outside of the memory die MD via the opening TV provided in the insulating layer 183. The exposed portion of the pad electrode region 193 functions as an external pad electrode P_{X}.

The lengths of the electrode MA30, including the external pad electrode P_{X}, in the X direction and the Y direction may be larger than the lengths of the electrode MA20, including the micropad electrode P_{M}, in the X direction and the Y direction.

### Manufacturing Method

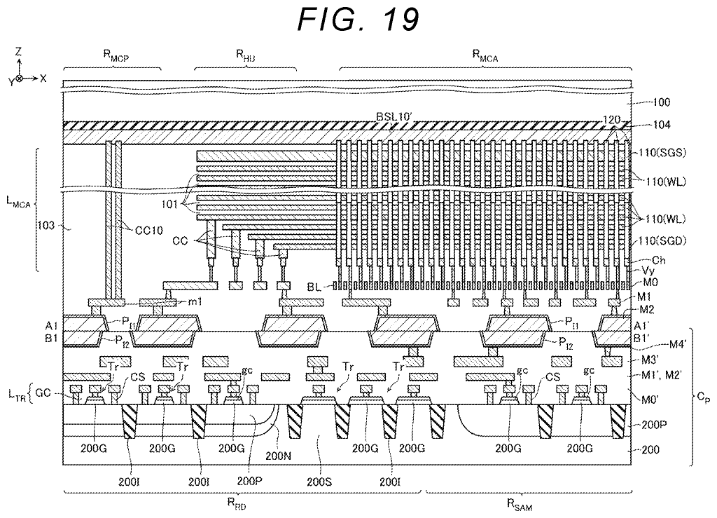

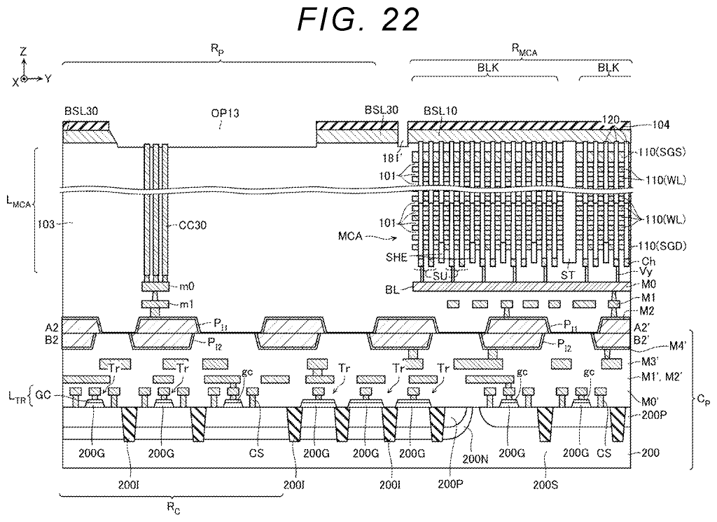

Next, a manufacturing method of the memory die MD according to the first embodiment will be described with reference to FIGS. 19 to 28. FIGS. 19 to 21, 23, 25, and 27 are schematic sectional views showing the manufacturing method, and show a cross section corresponding to FIG. 9. FIGS. 22, 24, 26, and 28 are schematic sectional views showing the manufacturing method, and show a cross section corresponding to FIG. 10.

In a case of manufacturing the memory die MD, first, a chip CM and a chip C_{P} are manufactured.

Next, as shown in FIG. 19, the wafer on which the chip C_{M} is formed and the wafer on which the chip C_{P} is formed are aligned and bonded to each other such that the first bonding electrode P_{I1} and the second bonding electrode P_{I2} are connected to each other. In this bonding step, for example, both wafers are brought into close contact with each other by pressing one wafer against the other wafer, and heat treatment or the like is performed. As a result, the wafer on which the chip C_{M} is formed is bonded to the wafer on which the chip C_{P} is formed via the first bonding electrode P_{I1} and the second bonding electrode P_{I2}.

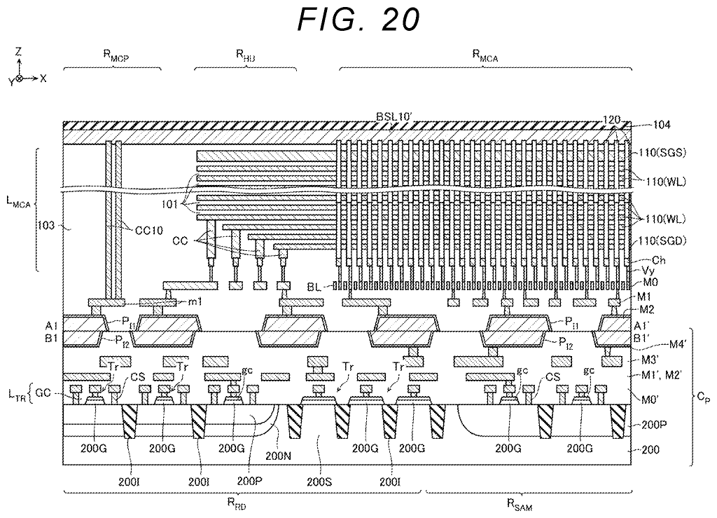

Next, for example, as shown in FIG. 20, the substrate 100 provided in the chip C_{M} is removed to expose the insulating layer 104 made of silicon oxide (SiO₂) or the like. The insulating layer 104 is, for example, a part of the insulating layer 182 (FIGS. 9 and 10). This step is performed by, for example, a method such as grinding processing and chemical mechanical polishing (CMP).

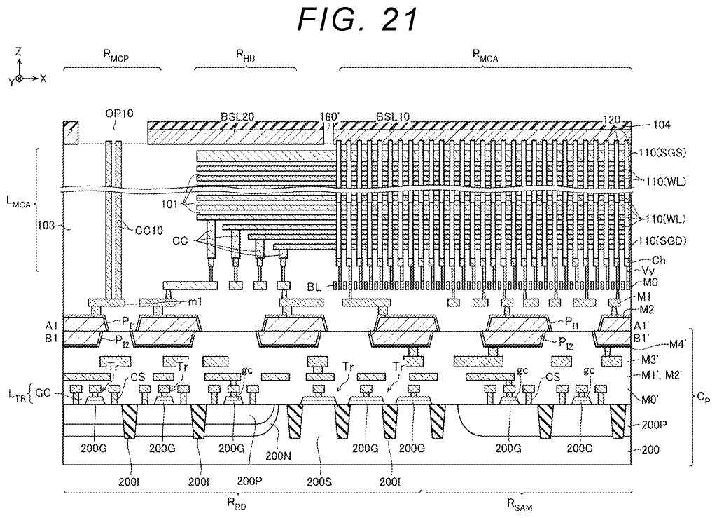

Next, for example, as shown in FIGS. 21 and 22, a resist is applied onto the insulating layer 104 to form a mask (not shown) by a photoetching method, and the opening OP10, the opening 180′, and the like (FIG. 21) and the opening OP13, the opening 181′, and the like (FIG. 22) are formed in the insulating layer 104 and the conductive layer BSL10′. As a result, the conductive layer BSL10, the conductive layer BSL20, and the conductive layer BSL30 are formed. This step is performed by, for example, a method such as reactive ion etching (RIE).

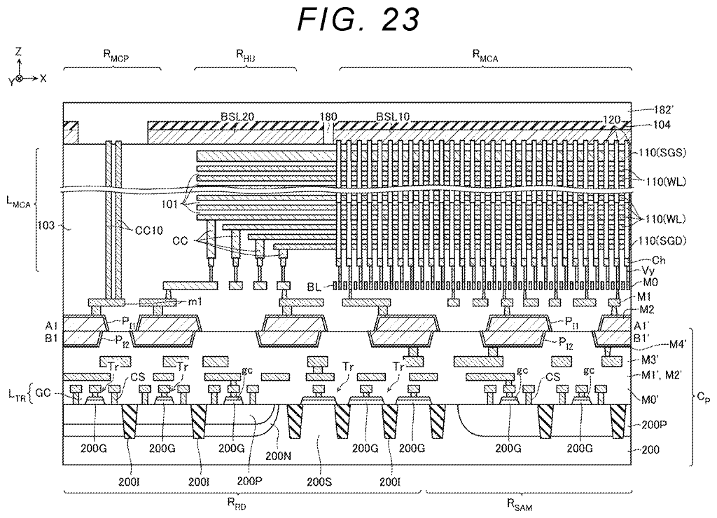

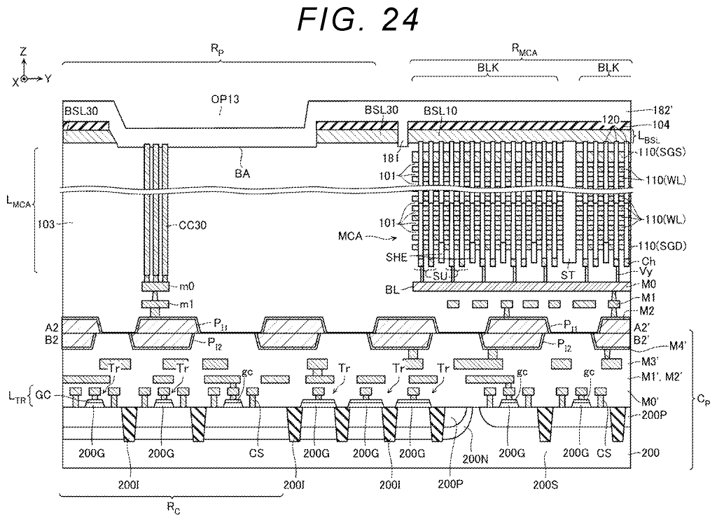

Next, for example, as shown in FIGS. 23 and 24, an insulating layer 182′ made of silicon oxide (SiO₂) or the like is formed on the upper surface of the insulating layer 104, inside the opening OP10 and the opening 180′ (FIG. 23), and inside the opening OP13 and the opening 181′ (FIG. 24). As a result, the slit 180 (FIG. 23) and the slit 181 (FIG. 24) are formed. This step is performed by, for example, a method such as chemical vapor deposition (CVD).

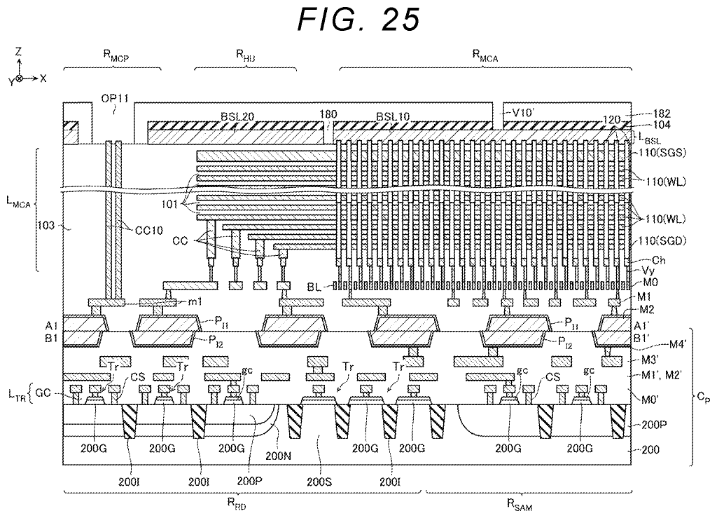

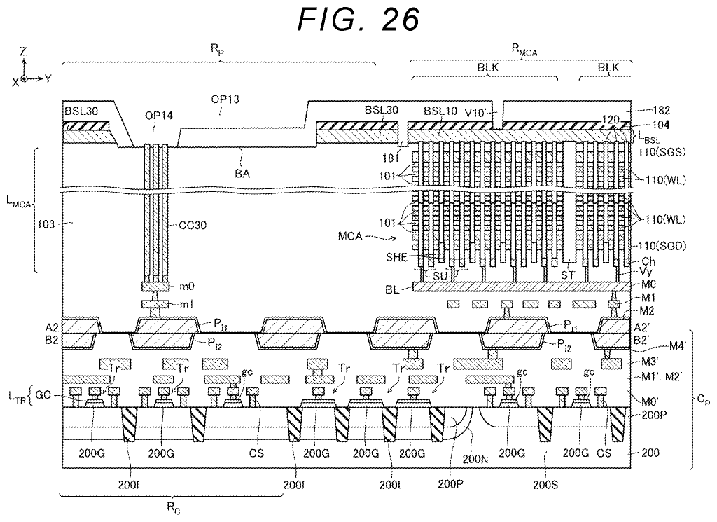

Next, for example, as shown in FIGS. 25 and 26, a resist is applied onto the insulating layer 182′ to form a mask (not shown) by a photoetching method, and the insulating layer 182, the opening V10′, and the openings OP11 (FIG. 25) and OP14 (FIG. 26) are formed. As a result, the upper end portion of the contact CC10 is exposed on the bottom surface of the opening OP11 (FIG. 25). In addition, the upper end portion of the contact CC30 is exposed on the bottom surface of the opening OP14 (FIG. 26). In addition, the conductive layer BSL10 is exposed on the bottom surface of the opening V10′. This step is performed by, for example, a method such as RIE.

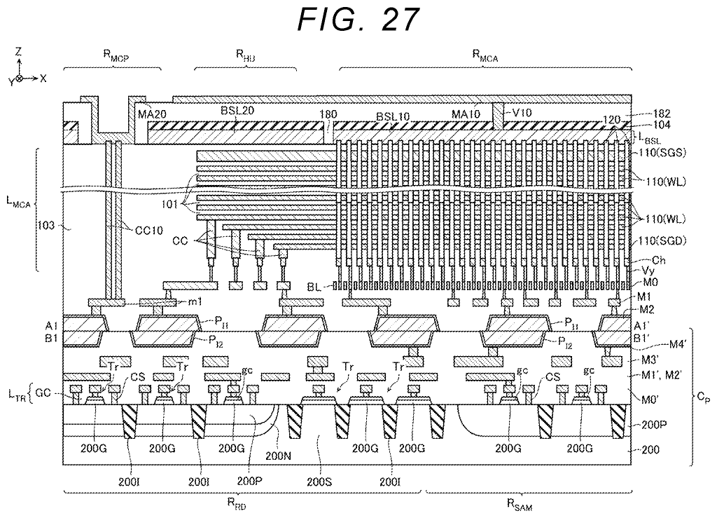

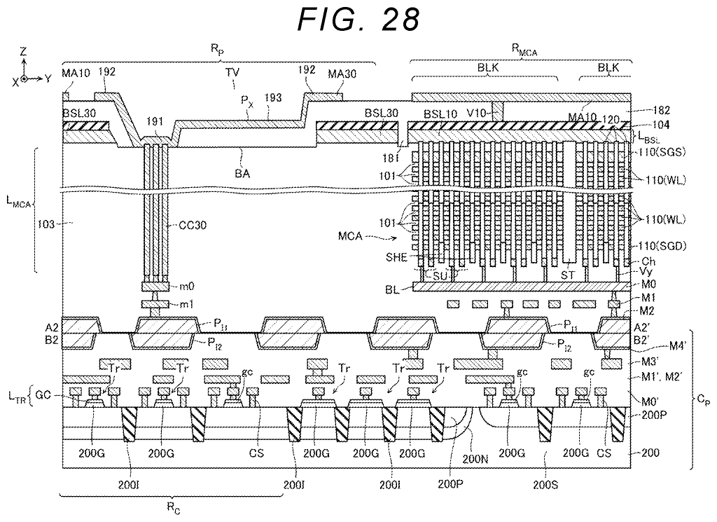

Next, for example, as shown in FIGS. 27 and 28, a conductive layer containing the same material as the wiring MA10, the electrode MA20, and the electrode MA30 is formed on the inner side surface and the bottom surface of the opening OP11 (FIG. 27), on the inner side surface and the bottom surface of the opening OP13 and the opening OP14 (FIG. 28), inside the opening V10′, and on the upper surface of the insulating layer 182. In addition, a predetermined wiring pattern including the wiring MA10, the electrode MA20, and the electrode MA30 is formed by a photoetching method. This step is performed by, for example, a method such as CVD and RIE.

Next, the insulating layer 183 is formed on the upper surface of the wiring MA10, the electrode MA20, the electrode MA30, and the like, and the opening TV is formed on the upper portion of the electrode MA30. This step is performed by, for example, methods such as CVD, CMP, and RIE. As a result, a structure as shown in FIGS. 9 and 10 is formed.

### Evaluation and Analysis Method Using Micropad Electrode P_{M}

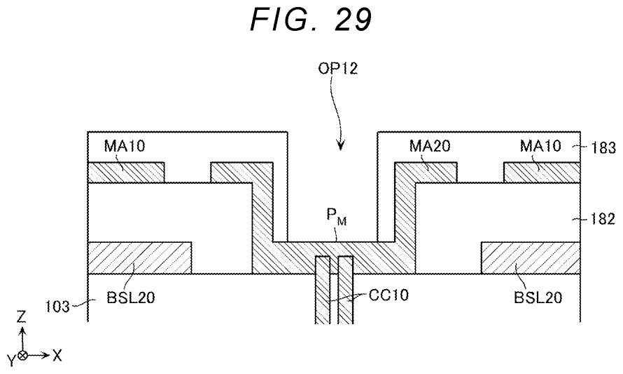

FIG. 29 is a schematic sectional view showing an evaluation and analysis method using the micropad electrode P_{M}.

The plurality of micropad electrodes P_{M} are each connected to, for example, a predetermined circuit, wiring, a transistor, or the like formed in the chip C_{P}.

In the evaluation and analysis, for example, as shown in FIG. 29, a part of the insulating layer 183 is removed to form an opening OP12, thereby exposing the surface of the micropad electrode P_{M}. The micropad electrodes P_{M} of the memory die MD other than the inspection target are basically not opened. After the opening OP12 is formed in the insulating layer 183, a conductive member that is electrically connected to the micropad electrode P_{M} may be formed on the upper surface of the insulating layer 183 by a method such as sputtering. Next, a voltage, current, or the like is measured by bringing an inspection probe of a test device having a function of a voltmeter, an ammeter, or the like into contact with the micropad electrode P_{M} or a conductive member that is electrically connected to the micropad electrode P_{M}. In a case of the measurement, a signal or the like may be input to the memory die MD via the external pad electrodes P_{X} (FIG. 6), and a read operation, a write operation, or the like may be executed by the memory die MD. As a result, it is possible to measure a voltage or the like during the read operation or the write operation of the wiring or the like in the memory die MD.

### Effects

The electrode MA20 including the micropad electrode P_{M} is formed at the same time as the wiring MA10 which is the auxiliary wiring of the source line SL, or the like. Therefore, the micropad electrode P_{M} can be relatively easily formed.

In addition, the micropad electrode P_{M} is configured with a low resistance material such as aluminum. Therefore, it is possible to provide an analysis pad having relatively low contact resistance.

In addition, the micropad electrode P_{M} can be exposed on the surface only by removing the insulating layer 183 made of polyimide or the like. Therefore, the evaluation and the analysis can be relatively easily performed.

### Second Embodiment

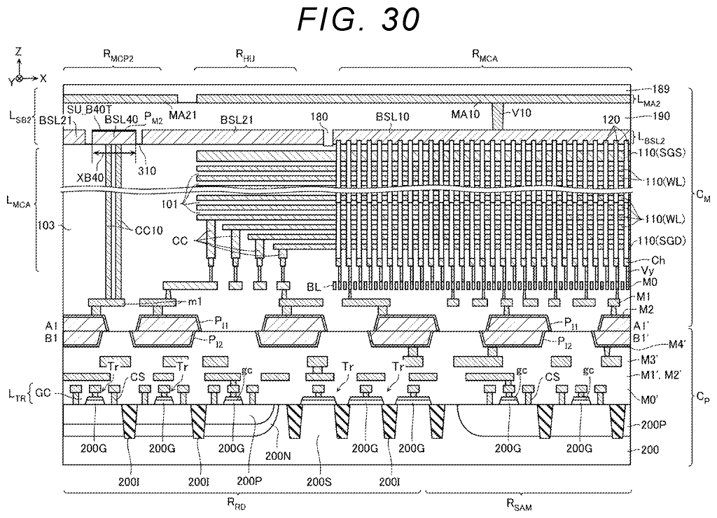

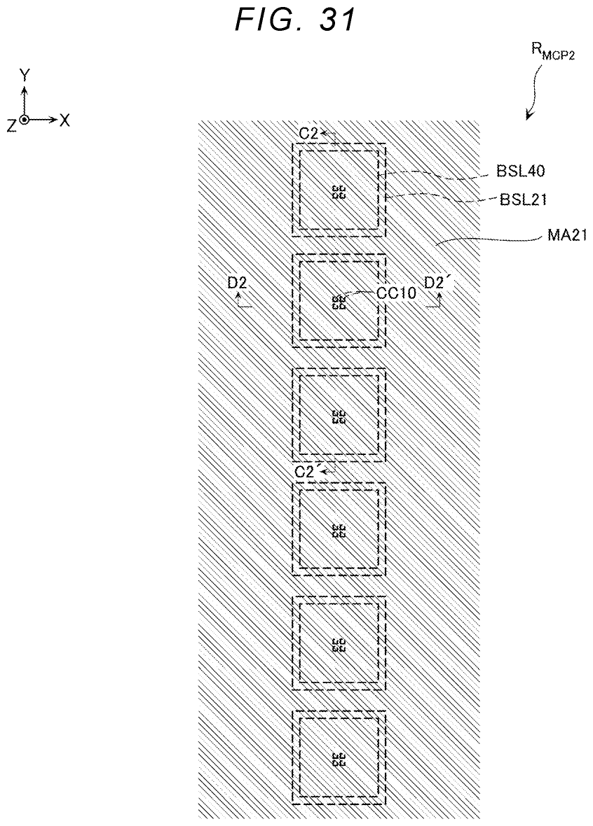

Next, a semiconductor storage device according to a second embodiment will be described with reference to FIGS. 30 to 39.

FIG. 30 is a schematic sectional view showing a partial configuration of a semiconductor storage device according to a second embodiment.

The semiconductor storage device according to the present embodiment is basically configured in the similar manner to the semiconductor storage device according to the first embodiment. However, the semiconductor storage device according to the present embodiment includes a micropad region R_{MCP2} (FIG. 30) instead of the micropad region R_{MCP} (FIG. 9). In addition, the semiconductor storage device according to the present embodiment includes a base layer L_{SB2} (FIG. 30) instead of the base layer L_{SB} (FIG. 9).

The base layer L_{SB2} includes, for example, as shown in FIG. 30, the insulating layer 189 provided on the rear surface of the chip C_{M}, the wiring layer L_{MA2} provided below the insulating layer 189, the insulating layer 190 provided below the wiring layer L_{MA2}, and the wiring layer L_{BSL2} provided below the insulating layer 190.

The insulating layer 189 contains, for example, the same material as the insulating layer 183.

The wiring layer L_{MA2} is basically configured in the same manner as the wiring layer L_{MA} (FIG. 9). However, the wiring layer L_{MA2} includes a conductive layer MA21 (FIG. 30) instead of the plurality of electrodes MA20, in the micropad region R_{MCP2}.

The conductive layer MA21 (FIG. 30) is electrically insulated from the contact CC10. The conductive layer MA21 is electrically insulated from the configuration in the chip C_{P}.

The conductive layer MA21 (FIG. 30) is separated from a conductive member BSL40 described below in the Z direction. The conductive layer MA21 entirely covers the surface SU_B40T (FIG. 30) of the conductive member BSL40 on the side opposite to the semiconductor substrate 200.

The conductive layer MA21 contains a conductive material such as aluminum (Al).

The insulating layer 190 contains, for example, the same material as the insulating layer 182 (FIG. 9).

The wiring layer L_{BSL2} is basically configured in the same manner as the wiring layer L_{BSL} (FIG. 9). However, the wiring layer L_{BSL2} includes the conductive member BSL21 and the conductive member BSL40 (FIG. 30) in the micropad region R_{MCP2}, instead of the conductive layer BSL20 (FIG. 9).

The conductive member BSL21 has an opening 310 (FIG. 30). The conductive member BSL21 is electrically insulated from the configuration such as the plurality of semiconductor pillars 120, the contact CC10, and the like, which are provided in the memory cell array layer L_{MCA}. The conductive member BSL21 includes, for example, a semiconductor layer made of polycrystalline silicon (Si) or the like into which an N-type impurity such as phosphorus (P) or a P-type impurity such as boron (B) is injected.

A slit 180 (FIG. 30) is provided between the conductive member BSL21 and the conductive layer BSL10, and a part of the insulating layer 190 is provided in the slit 180. The conductive member BSL21 and the conductive layer BSL10 are electrically insulated from each other.

The conductive member BSL40 is provided inside the opening 310 of the conductive member BSL21. The conductive member BSL40 is connected to one end of the plurality of contacts CC10. The conductive member BSL40 is electrically connected to the configuration in the chip C_{P}, for example, via a plurality of contacts CC10 and the like. The conductive member BSL40 functions as a micropad electrode P_{M2}. The conductive member BSL40 includes, for example, a semiconductor layer made of polycrystalline silicon (Si) or the like into which an N-type impurity such as phosphorus (P) or a P-type impurity such as boron (B) is injected.

The micropad electrode P_{M2} is a pad electrode for evaluating and analyzing a circuit, wiring, a transistor, and the like inside the memory die MD, similarly to the micropad electrode P_{M}.

A length XB40 (FIG. 30) of the conductive member BSL40 in the X direction is smaller than a length XB10 (FIG. 13) of the conductive layer BSL10 in the X direction.

In addition, similarly, the length of the conductive member BSL40 in the Y direction is smaller than the length of the conductive layer BSL10 in the Y direction.

### Arrangement Example of Micropad Region R_{MCP2}

The micropad region R_{MCP2} is basically arranged in the same manner as the micropad region R_{MCP} described with reference to FIG. 13.

For example, the micropad electrodes P_{M2} provided in such a micropad region R_{MCP2} are provided between the memory plane MP and the memory plane MP that are arranged in the X direction.

In addition, similarly to the arrangement example of the conductive layer BSL20 shown in FIG. 13, the conductive member BSL21 (FIG. 30) is provided between the memory plane MP and the memory plane MP that are arranged in the X direction, in correspondence with one or a plurality of the micropad regions R_{MCP2}. The conductive member BSL21 is separated from the conductive layer BSL10 in the X direction.

A plurality of the conductive members BSL21 may be arranged, for example, between two conductive layers BSL10 adjacent to each other in the X direction. Even in such a case, the slits 180 are formed between the plurality of conductive members BSL21 and the conductive layer BSL10, and the conductive layer BSL10 is separated from the plurality of conductive members BSL21.

Detailed Configuration Example of Micropad Region R_{MCP2}

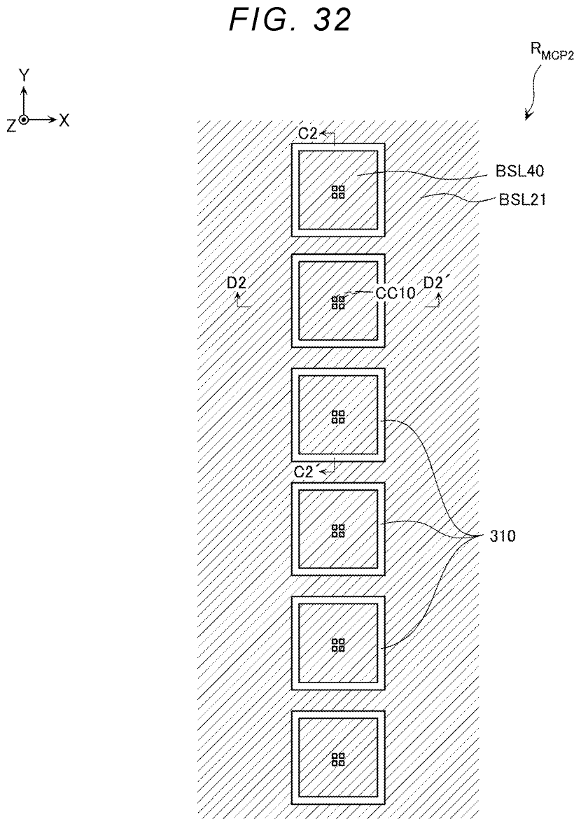

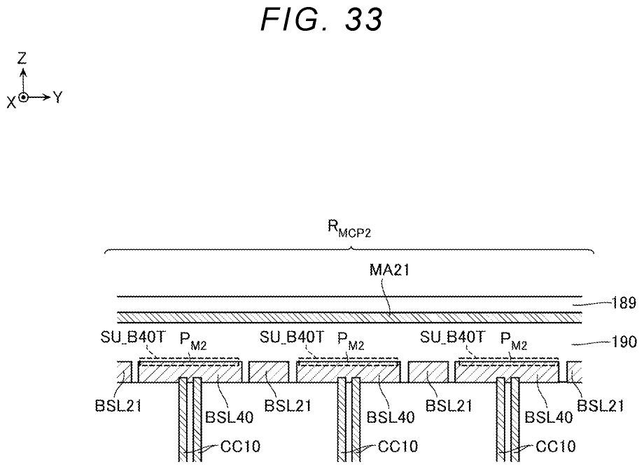

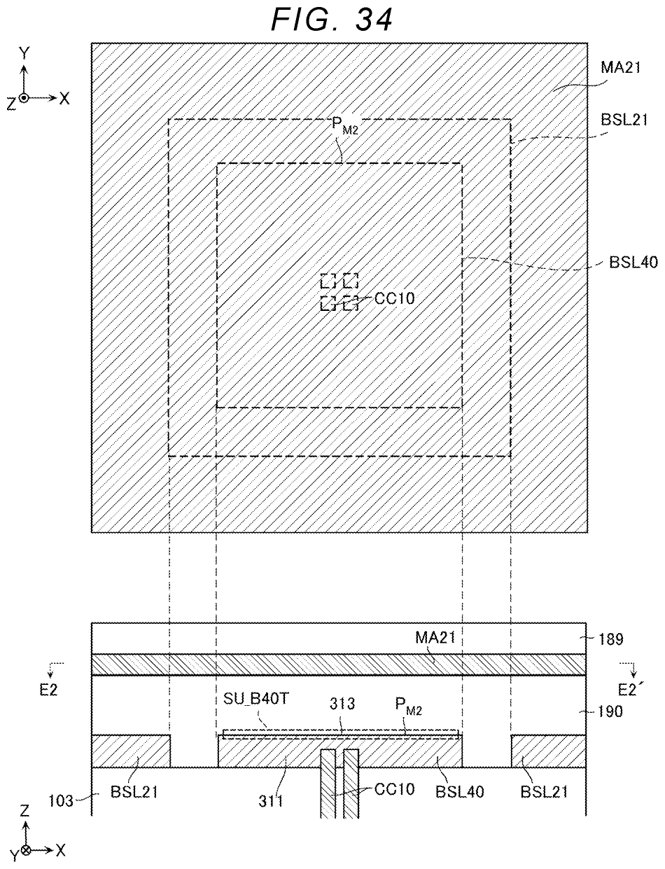

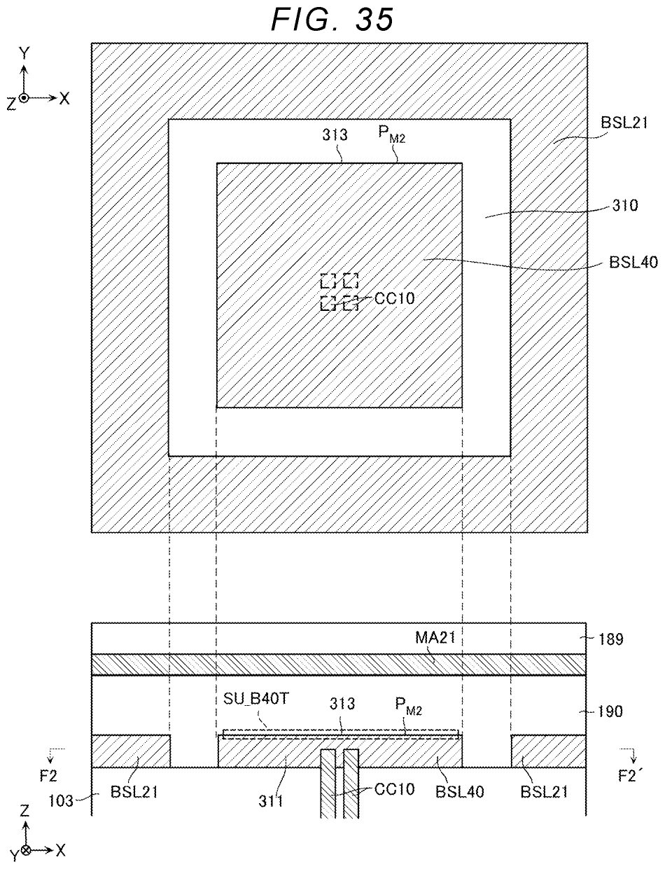

Next, a detailed configuration example of the micropad region R_{MCP2} will be described with reference to FIGS. 30 to 35. FIG. 31 is a top view of the wiring layer L_{MA2} in the micropad region R_{MCP2} as viewed from the positive side in the Z direction. FIG. 32 is a top view of the wiring layer L_{BSL2} in the micropad region R_{MCP2} as viewed from the positive side in the Z direction. FIG. 33 is a sectional view taken along line C2-C2′ in FIG. 31 and FIG. 32 and viewed from the arrow direction (positive side in the X direction). The lower diagram of FIG. 34 and the lower diagram of FIG. 35 are sectional views taken along line D2-D2′ in FIG. 31 and FIG. 32 and viewed from the arrow direction (negative side in the Y direction). The upper diagram of FIG. 34 is a sectional view taken along line E2-E2′ in the lower diagram of FIG. 31 and viewed from the arrow direction (positive side in the Z direction). The upper diagram of FIG. 35 is a sectional view taken along line F2-F2′ in the lower diagram of FIG. 32 and viewed from the arrow direction (positive side in the Z direction).

The conductive layer MA21 is provided flatways over a region facing the plurality of micropad electrodes P_{M2}, for example, as shown in FIGS. 31 and 33. The conductive layer MA21 is not provided with an opening.

For example, as shown in FIG. 33, the conductive layer MA21 entirely covers a surface SU_B40T of each of the plurality of adjacent conductive members BSL40 on a side opposite to the semiconductor substrate 200.

The conductive member BSL21 is provided with a plurality of the openings 310 arranged in the Y direction, for example, as shown in FIG. 32. The opening 310 has, for example, a substantially quadrangular shape as viewed from the positive side in the Z direction. The opening 310 is formed in a size that can accommodate, for example, the conductive member BSL40.

A plurality of conductive members BSL40 are arranged in the Y direction, for example, as shown in FIGS. 32 and 33. The conductive member BSL40 is formed as an isolated pattern separated from the surrounding conductive member BSL21 as viewed from the positive side in the Z direction (FIG. 32). The conductive member BSL40 has, for example, a substantially quadrangular shape as viewed from the positive side in the Z direction.

A part of the insulating layer 190 is provided between the conductive member BSL40 and the conductive member BSL21 (FIG. 33).

The conductive member BSL40 functions as a connection portion 311 connected to the upper end of the contact CC10, for example, as shown in the lower diagram of FIG. 34. In addition, a pad electrode region 313 functioning as a micropad electrode P_{M2} is provided on the upper surface of the connection portion 311.

The connection portion 311 is formed on the upper surface of the insulating layer 103 (lower diagram of FIG. 34). The connection portion 311 is connected to the contact CC10 in the vicinity of the center in the X direction and the Y direction. The connection portion 311 has, for example, a substantially quadrangular shape extending in the X direction and the Y direction. The upper surface of the connection portion 311 is covered with the insulating layer 189 and is not exposed to the outside of the memory die MD.

### Manufacturing Method

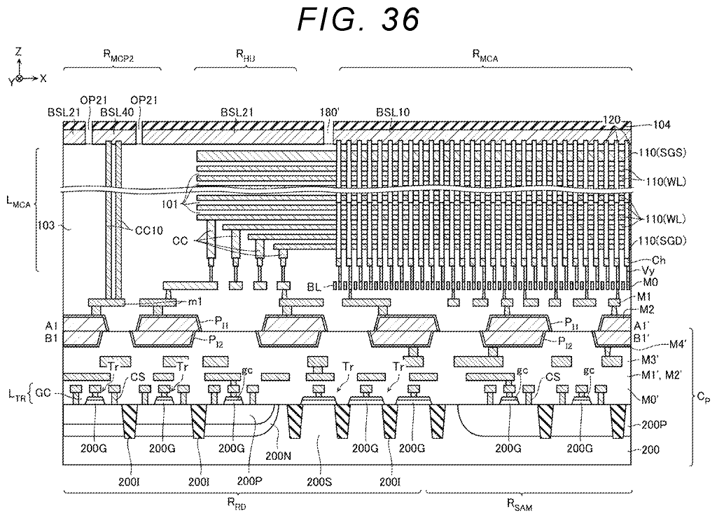

Next, a manufacturing method of the memory die MD according to the second embodiment will be described with reference to FIGS. 22, 24, 26, and 28, and FIGS. 36 to 38. FIGS. 36 to 38 are schematic sectional views showing the manufacturing method, and show a cross section corresponding to FIG. 30. In the description of the manufacturing method of the present embodiment, the insulating layer 182 and the insulating layer 183 shown in FIGS. 22, 24, 26, and 28 are read as the insulating layer 190 and the insulating layer 189, respectively.

The memory die MD according to the present embodiment is basically manufactured in the same manner as the memory die MD according to the first embodiment. However, in the manufacturing method of the memory die MD according to the present embodiment, the steps shown in FIGS. 22, 24, 26, and 28, and FIGS. 36 to 38 are performed after the steps described with reference to FIGS. 19 and 20.

For example, in the steps shown in FIGS. 36 and 22, a resist is applied onto the insulating layer 104 (FIG. 20) to form a mask (not shown) by a photoetching method, and the opening OP21, the opening 180′, and the like (FIG. 36) and the opening OP13, the opening 181′, and the like (FIG. 22) are formed in the insulating layer 104 and the conductive layer BSL10′ (FIG. 20). As a result, the conductive layer BSL10, the conductive member BSL21, the conductive layer BSL30, and the conductive member BSL40 are formed. This step is performed by, for example, a method such as RIE.

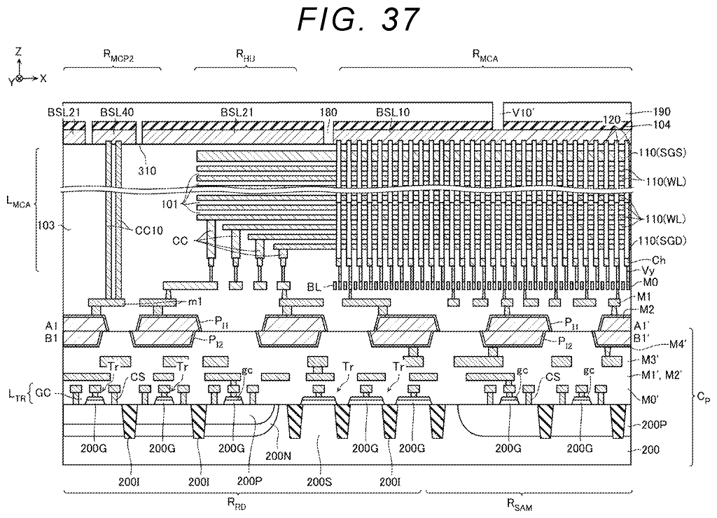

Next, for example, as shown in FIGS. 37 and 24, an insulating layer 190 is formed on the upper surface of the insulating layer 104, inside the opening OP21 and the opening 180′ (FIG. 37), and inside the opening OP13 and the opening 181′ (FIG. 24). As a result, the opening 310, the slit 180, and the slit 181 are formed. This step is performed by, for example, a method such as CVD.

In addition, for example, as shown in FIGS. 37 and 26, the openings V10′ and OP14 (FIG. 26) are formed in the same manner as in the step described with reference to FIG. 25. As a result, the conductive layer BSL10 is exposed on the bottom surface of the opening V10′. In addition, the upper end portion of the contact CC30 is exposed on the bottom surface of the opening OP14 (FIG. 26).

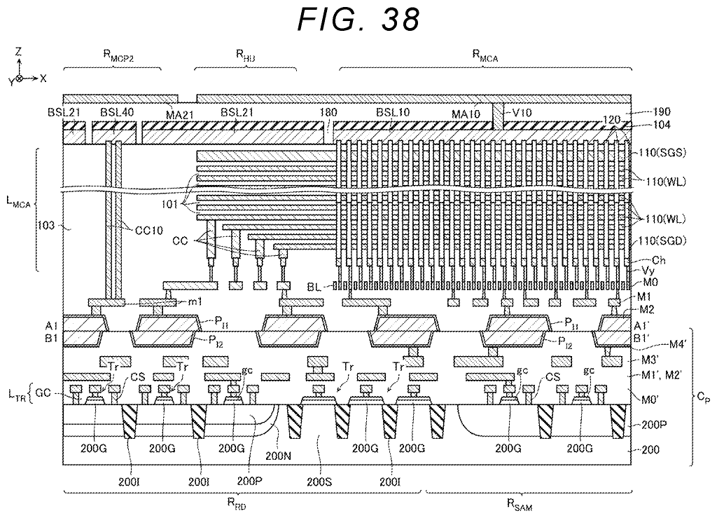

Next, for example, as shown in FIGS. 38 and 28, a conductive layer containing the same material as the wiring MA10 is formed inside the opening V10′, on the upper surface of the insulating layer 190, and on the inner side surface and the bottom surface of the opening OP13 and the opening OP14 (FIG. 28). Next, a mask (not shown) is formed by a photoetching method to form a predetermined wiring pattern including the wiring MA10, the conductive layer MA21, and the electrode MA30. This step is performed by, for example, a method such as CVD.

Next, the insulating layer 189 is formed on the upper surface of the conductive layer MA21. This step is performed by, for example, methods such as CVD and CMP. As a result, a structure as shown in FIG. 30 is formed.

### Evaluation and Analysis Method Using Micropad Electrode PM2

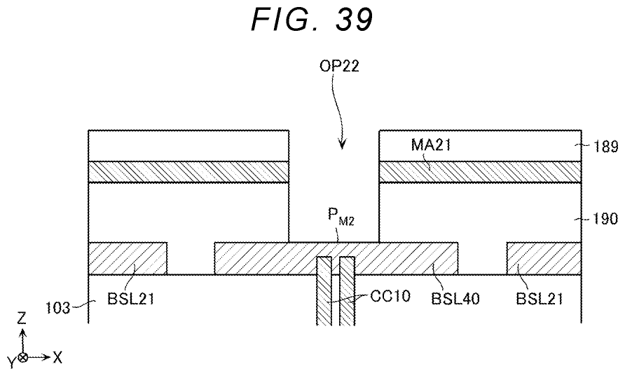

FIG. 39 is a schematic sectional view showing an evaluation and analysis method using the micropad electrodes P_{M2}.

The micropad electrode P_{M2} is basically connected to a predetermined circuit, wiring, transistor, or the like in the same manner as the micropad electrode P_{M}.

In addition, in a case of evaluation and analysis, the micropad electrode P_{M2} is opened in the same manner as the micropad electrode P_{M}, and is used for the inspection.

When opening the micropad electrode P_{M2}, for example, as shown in FIG. 39, a part of the insulating layer 189, a part of the conductive layer MA21, and a part of the insulating layer 190 are removed to form an opening OP22, thereby exposing the surface of the micropad electrode P_{M2}. The micropad electrodes P_{M2} of the memory die MD other than the inspection target are basically not opened.

### Effects

The stress in bending the chip is likely to be concentrated in the vicinity of the center of the memory die MD (FIG. 6) in the longitudinal direction. In a memory die MD to which the chip C_{M} is bonded as shown in FIG. 13, when the micropad region R_{MCP2} is provided in the vicinity of the center in the X direction which is the longitudinal direction of the chip, the bending stress may be concentrated in the micropad region R_{MCP2}. When the structural uneven portion is formed in the vicinity of the surface layer of the micropad region R_{MCP2} on the rear surface side, the memory die MD may be likely to break from such a portion.

In the present embodiment, for example, in the micropad region R_{MCP2}, the insulating layer 189, the conductive layer MA21, and the insulating layer 190 in the vicinity of the surface layer on the rear surface side are each formed flatways (FIG. 30). With such a structure, even when the bending stress is concentrated in the micropad region R_{MCP2}, the breakage of the memory die MD from the micropad region R_{MCP2} can be prevented.

In addition, the conductive member BSL40 functioning as the micropad electrode P_{M2} is formed at the same time as the conductive layer BSL10 functioning as the source line SL (FIG. 36). Therefore, the micropad electrode P_{M2} can be relatively easily formed.

### Other Embodiments

Hitherto, the semiconductor storage device according to the first embodiment and the second embodiment has been described. However, the semiconductor storage device according to these embodiments is merely an example, and specific configurations, operations, and the like may be appropriately adjusted.

For example, in the above description, an example (FIG. 13) is described in which the micropad region R_{MCP} and the micropad region R_{MCP2} are arranged between the adjacent memory plane MP and memory plane MP, and the like. However, the arrangement of the micropad region R_{MCP} and the micropad region R_{MCP2} may be appropriately adjusted.

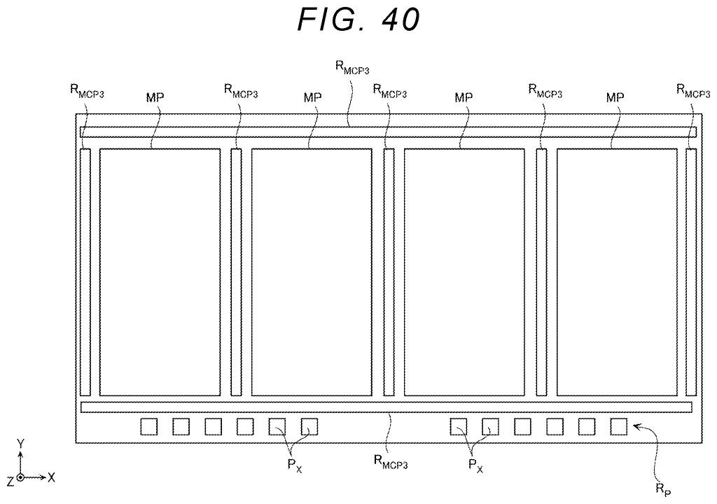

FIG. 40 is a top view showing an arrangement example of the micropad region R_{MC}P and the micropad region R_{MCP2} in the chip C_{M}. In FIG. 40, the micropad region R_{MC}P or the micropad region R_{MCP2} is denoted by a micropad region R_{MCP3}.

The micropad region R_{MCP3} may be provided, for example, as shown in FIG. 40, not only between the adjacent memory plane MP and memory plane MP and the both end sides of the chip C_{M} in the X direction, but also in the vicinity of the positive side end of the chip C_{M} in the Y direction and between the memory plane MP and the peripheral region R_{P}.

### OTHERS

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a substrate;
a first wiring layer;
a second wiring layer disposed between the substrate and the first wiring layer;
a memory cell array layer disposed between the substrate and the second wiring layer; and
a first insulating layer disposed on a side opposite to the substrate with respect to the first wiring layer,
wherein the memory cell array layer includes
a plurality of first conductive layers arranged in a first direction intersecting a surface of the substrate,
a first semiconductor layer extending in the first direction and facing the plurality of first conductive layers,
a first charge storage layer disposed between the plurality of first conductive layers and the first semiconductor layer,
a first contact extending in the first direction, and
a second contact extending in the first direction,
the second wiring layer including a second conductive layer electrically connected to one end of the first semiconductor layer,
the first wiring layer includes
a first electrode electrically connected to the first contact, and
a second electrode electrically connected to the second contact,
at least a part of a surface of the first electrode on a substrate side and at least a part of a surface of the second electrode on the substrate side are closer to the substrate than a surface of the second conductive layer on the side opposite to the substrate in the first direction,
a surface of the first electrode on the side opposite to the substrate includes a region not covered with the first insulating layer, and
a surface of the second electrode on the side opposite to the substrate is entirely covered with the first insulating layer.

2. The semiconductor storage device according to claim 1, further comprising:
a first memory plane and a second memory plane arranged in a second direction intersecting the first direction,
wherein, in the first memory plane, the memory cell array layer includes the plurality of first conductive layers, the first semiconductor layer, and the first charge storage layer,
in the second memory plane, the memory cell array layer includes
a plurality of third conductive layers separated from the plurality of first conductive layers in the second direction and arranged in the first direction,
a second semiconductor layer extending in the first direction and facing the plurality of third conductive layers, and
a second charge storage layer disposed between the plurality of third conductive layers and the second semiconductor layer, and
wherein the second electrode is disposed between the first memory plane and the second memory plane.

3. The semiconductor storage device according to claim 2,
wherein, in the first memory plane, the second wiring layer includes the second conductive layer,
in the second memory plane, the second wiring layer includes a fourth conductive layer electrically connected to one end of the second semiconductor layer,
between the first memory plane and the second memory plane, the second wiring layer includes a fifth conductive layer separated from the second conductive layer and the fourth conductive layer,
the fifth conductive layer includes a plurality of openings that are arranged in a third direction intersecting the first direction and the second direction, and
at least a part of the second electrode is disposed inside any one of the plurality of openings to be separated from the fifth conductive layer as viewed from the first direction.

4. The semiconductor storage device according to claim 1,
wherein the second electrode includes
a first portion in contact with one end portion of the second contact,
a second portion disposed at a position that: (a) does not overlap with the first portion as viewed from the first direction, and (b) is further from the substrate with respect to the second conductive layer, and
a third portion connected to the first portion and the second portion and extending from the first portion to the second portion.

5. The semiconductor storage device according to claim 1, further comprising:
a bonding wire in contact with the first electrode.

6. The semiconductor storage device according to claim 1,
wherein the second conductive layer contains polycrystalline silicon.

7. The semiconductor storage device according to claim 1,
wherein the first wiring layer includes wiring electrically connected to the second conductive layer.

8. A semiconductor storage device comprising:
a substrate;
a first wiring layer;
a second wiring layer disposed between the substrate and the first wiring layer; and
a memory cell array layer disposed between the substrate and the second wiring layer,
wherein the memory cell array layer includes
a plurality of first conductive layers arranged in a first direction intersecting a surface of the substrate,
a first semiconductor layer extending in the first direction and facing the plurality of first conductive layers,
a first charge storage layer disposed between the plurality of first conductive layers and the first semiconductor layer,
a first contact extending in the first direction, and
a second contact extending in the first direction,
the second wiring layer includes
a second conductive layer electrically connected to one end of the first semiconductor layer, and
a first conductive member connected to one end of the second contact and having lengths in (i) a second direction intersecting the first direction and (ii) a third direction intersecting the first direction and the second direction that are smaller than lengths of the second conductive layer in the second direction and the third direction, respectively, and
the first wiring layer includes
a first electrode electrically connected to the first contact, and
another conductive layer separated from the first conductive member in the first direction and entirely covering a surface of the first conductive member on the side opposite to the substrate.

9. The semiconductor storage device according to claim 8,
wherein the memory cell array layer includes a third contact extending in the first direction,
the second wiring layer includes a second conductive member connected to one end of the third contact and having lengths (i) in the second direction and (ii) the third direction that are smaller than the lengths of the second conductive layer in the second direction and the third direction, respectively, and
the other conductive layer is separated from the second conductive member in the first direction and entirely covers surfaces of the first conductive member and the second conductive member on the side opposite to the substrate.

10. The semiconductor storage device according to claim 8, further comprising:
a first memory plane and a second memory plane arranged in the second direction,
wherein, in the first memory plane, the memory cell array layer includes the plurality of first conductive layers, the first semiconductor layer, and the first charge storage layer,
in the second memory plane, the memory cell array layer includes
a plurality of third conductive layers separated from the plurality of first conductive layers in the second direction, and arranged in the first direction,
a second semiconductor layer extending in the first direction and facing the plurality of third conductive layers, and
a second charge storage layer disposed between the plurality of third conductive layers and the second semiconductor layer, and
the first conductive member is disposed between the first memory plane and the second memory plane.

11. The semiconductor storage device according to claim 10,
wherein, in the first memory plane, the second wiring layer includes the second conductive layer,
in the second memory plane, the second wiring layer includes a fourth conductive layer electrically connected to one end of the second semiconductor layer,
between the first memory plane and the second memory plane, the second wiring layer includes a third conductive member separated from the second conductive layer and the fourth conductive layer,
the third conductive member includes a plurality of openings that are arranged in the third direction, and
the first conductive member is disposed inside any one of the plurality of openings such as to be separated from the third conductive member as viewed from the first direction.

12. The semiconductor storage device according to claim 11,
wherein an insulating layer is disposed between the third conductive member and the first conductive member.

13. The semiconductor storage device according to claim 8,
wherein the second contact and the other conductive layer are electrically insulated from each other.

14. The semiconductor storage device according to claim 8, further comprising:
a bonding wire in contact with the first electrode.

15. The semiconductor storage device according to claim 8,
wherein the second conductive layer and the first conductive member contain polycrystalline silicon.

16. The semiconductor storage device according to claim 8,
wherein the first wiring layer includes wiring electrically connected to the second conductive layer.

17. The semiconductor storage device according to claim 1, wherein the first charge storage layer is formed of silicon nitride.

18. The semiconductor storage device according to claim 1, further comprising a tunnel insulating film and a block insulating film, wherein the first charge storage layer is disposed between the tunnel insulating film and the block insulating film.

19. The semiconductor storage device according to claim 8, wherein the first charge storage layer is formed of silicon nitride.

20. The semiconductor storage device according to claim 8, further comprising a tunnel insulating film and a block insulating film, wherein the first charge storage layer is disposed between the tunnel insulating film and the block insulating film.
